(19) United States
(12) Patent Application Publication
(10) Pub. No.: US 2025/0265148 A1
(43) Pub. Date: Aug. 21, 2025

(54) MEMORY DEVICE INCLUDING SETTING DATA AND OPERATING METHOD OF THE MEMORY DEVICE

(71) Applicant: SAMSUNG ELECTRONICS CO., LTD., SUWON-SI (KR)

(72) Inventor: SANGIN PARK, Suwon-si (KR)

(21) Appl. No.: 19/006,553

(22) Filed: Dec. 31, 2024

(30) Foreign Application Priority Data
Feb. 16, 2024 (KR) 10-2024-0022677

(51) Int. Cl. G06F 11/10

(52) U.S. Cl. CPC G06F 11/1044

(57) ABSTRACT

A memory device includes a memory cell arrange storing reference setting data including information regarding setting operations of the memory device. The reference setting data is loaded from the memory cell array and stored as load setting data in a latch circuit. The reference setting data stored in the memory cell array and the load setting data stored in the latch circuit are compared to determine whether the reference setting data and the load setting data match, and when it is determined that the reference setting data and the load setting data do not match, the reference setting data is loaded from the memory cell array back to the latch circuit.

### CROSS-REFERENCE TO RELATED APPLICATION

This application claims priority under 35 U.S.C. § 119 to Korean Patent Application No. 10-2024-0022677, filed on Feb. 16, 2024, in the Korean Intellectual Property Office, the disclosure of which is incorporated by reference in its entirety herein.

### 1. TECHNICAL FIELD

The inventive concept relates to a memory device and an operating method of the memory device, and more particularly, to a memory device configured to increase the reliability of setting data.

### 2. DISCUSSION OF RELATED ART

A non-volatile memory device includes a plurality of memory cells configured to store data in a non-volatile manner so the data is maintained even after a power-off. A flash memory may be used to implement the non-volatile memory device. The flash memory device may be used in mobile phones, digital cameras, portable digital assistants (PDA), mobile computer devices, stationary computer devices, and other devices.

The non-volatile memory device may be configured to store setting data for operations of memory cells included in the non-volatile memory device. A process of setting various operation conditions of a memory system including the non-volatile memory device may be performed based on setting data stored in the non-volatile memory device. Since the setting data stored in the non-volatile memory device includes important information related to management of the memory system, it is required to secure the reliability of the setting data. Accordingly, a technology to increase the reliability of the setting data is needed.

### SUMMARY

An embodiment of the inventive concept provides a memory device having increased reliability by rapidly determining an error of setting data stored in a latch circuit of the memory device and rapidly recovering the setting data when an error occurs, and an operating method of the memory device.

According to an aspect of the inventive concept, there is provided a memory device including a memory cell array, a control logic, and a latch circuit. The memory cell array includes a plurality of memory cells and stores reference setting data including information regarding setting operations of the memory device. The control logic is configured to control memory operations on the memory cell array. The latch circuit includes a plurality of latches, wherein reference setting data including information regarding setting operations of the memory device is stored in the memory cell array, the reference setting data is loaded from the memory cell array and stored as load setting data in the latch circuit, the control logic is further configured to compare the reference setting data stored in the memory cell array with the load setting data stored in the latch circuit, determine whether the reference setting data and the load setting data match, and perform a recovery operation to load the reference setting data from the memory cell array back to the latch circuit when determining that the reference setting data and the load setting data do not match.

According to another aspect of the inventive concept, there is provided a memory device including a memory cell array, a latch circuit, a comparison circuit, and a determination circuit. The memory cell array stores reference setting data including information regarding setting operations of the memory device. Reference setting data is loaded from the memory cell array and stored as load setting data in the latch circuit. The comparison circuit is configured to compare the reference setting data output from the memory cell array and the load setting data output from the latch circuit to output a comparison signal. The determination circuit is configured to generate a determination signal for controlling a recovery operation to load the reference setting data from the memory cell array back to the latch circuit, based on the comparison signal indicating that the reference setting data and the load setting data do not match.

According to another aspect of the inventive concept, there is provided an operating method of a memory device. The operating method includes: outputting, from a memory cell array of the memory device to a page buffer of the memory device, setting data including information regarding setting operations of the memory device; outputting the setting data from the memory cell array to a latch circuit of the memory device; comparing the setting data stored in the page buffer with the setting data stored in the latch circuit for outputting the comparison signal; and generating a determination signal for controlling a recovery operation to output the setting data from the memory cell array back to the latch circuit, based on the comparison signal.

### BRIEF DESCRIPTION OF THE DRAWINGS

Embodiments will be more clearly understood from the following detailed description taken in conjunction with the accompanying drawings.

FIG. 1 is a block diagram of a host-memory system according to an embodiment.

FIG. 2 is a diagram for describing a memory device according to an embodiment.

FIG. 3 is a perspective view of a memory block according to an embodiment.

FIG. 4 is a circuit diagram of a memory block according to an embodiment.

FIG. 5 is a block diagram for describing a recovery circuit according to an embodiment.

FIG. 6 is a diagram for describing an accumulator according to an embodiment.

FIG. 7 is a flowchart for describing an operating method of a memory device according to an embodiment.

FIG. 8 is a flowchart for describing an operating method of a recovery circuit according to an embodiment.

FIG. 9 is a flowchart for describing an operating method of a recovery circuit according to an embodiment.

FIG. 10 is a diagram for describing operations of a control logic according to an embodiment.

FIG. 11 is a diagram for describing a recovery operation according to an embodiment.

FIG. 12A is a block diagram for describing operations of a recovery circuit according to an embodiment.

FIG. 12B is a block diagram for describing operations of a recovery circuit according to an embodiment.

FIG. 13A is a block diagram for describing operations of an accumulator according to an embodiment.

FIG. 13B is a block diagram for describing operations of an accumulator according to an embodiment.

FIG. 14 is a diagram for describing sub-accumulation data according to an embodiment.

FIG. 15 illustrates a system to which a memory device according to an embodiment is applied.

### DETAILED DESCRIPTION

Hereinafter, embodiments will be described in detail with reference to the accompanying drawings. Same reference numerals will be used for same components in the drawings, and thus same descriptions thereof may not be repeatedly provided.

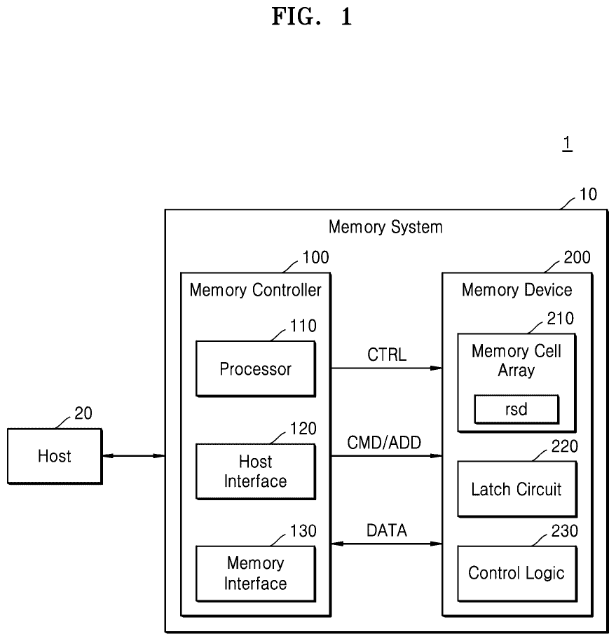

FIG. 1 is a block diagram of a host-memory system 1 according to an embodiment.

Referring to FIG. 1, the host-memory system 1 includes a host 20 and a memory system 10. The memory system 10 includes a memory controller 100 and a memory device 200. The memory device 200 includes a memory cell array 210, a latch circuit 220, and a control logic 230. The memory controller 100 includes a processor 110, a host interface 120 (e.g., a first interface circuit), and a memory interface 130 (e.g., a second interface circuit).

The host 20 may be configured to communicate with the memory system 10 through an interface. Here, the interface may be implemented as a non-volatile memory express (NVMe), an NVMe Management Interface (NVMe MI), or an NVMe Over Fabric (NVMeof). The host 20 may be configured to control general operations of the memory system 10. For example, the host 20 may be configured to store data in the memory system 10 or read data stored in the memory system 10.

The host 20 may be configured to provide, to the memory system 10, write requests to request storing of data in the memory system 10. In addition, the host 20 may be configured to provide, to the memory system 10, logic addresses and data to identify data. In an embodiment, a logic address may be included in a write request.

The host 20 may be configured to provide, to the memory system 10, read requests to request provision of the data stored in the memory system 10. In addition, the host 20 may also be configured to provide the logic addresses to identify data to the memory system 10. In an embodiment, the logic address may be included in a read request.

The memory system 10 may include the memory controller 100 and the memory device 200. For example, the memory controller 100 and the memory device 200 may be integrated in a semiconductor device. For example, the memory system 10 may be implemented as an internal memory embedded in an electronic device, and may include an embedded Universal Flash Storage (UFS) memory device, an embedded Multi-Media Card (eMMC), or a solid state drive (SSD). In some embodiments, the memory system 10 may be implemented as an external memory attachable to/detached from electronic devices, and for example, may include a UFS memory card, a Compact Flash (CF) card, a Secure Digital (SD) card, a Micro-Secure Digital (Micro-SD) card, a Mini-Secure Digital (Mini-SD) card, an extreme Digital (xD) card, or a memory stick.

The memory controller 100 may be configured to control the memory device 200 to read data stored in the memory device 200 or write (or program) the data to the memory device 200 in response to a request (e.g., a write request or read request) provided from the host 20. Particularly, the memory controller 100 may be configured to control write operations (or programming operations), read operations, and erase operations on the memory device 200 by controlling commands (CMD)/addresses (ADD) and control signals (CTRL). In addition, data DATA to be written and data DATA to read may be transmitted and received between the memory controller 100 and the memory device 200.

The memory controller 100 may include the processor 110, the host interface 120, and the memory interface 130. The processor 110 may be configured to control general operations of the memory controller 100. For example, the processor 110 may include a central processing unit (CPU), but is not limited thereto. More particularly, the processor 110 may be configured to control the memory controller 100 to receive commands from the host 20 and perform operations according to the commands. The processor 110 may be configured to perform garbage collection, address mapping, wear leveling and the like to manage the memory device 200 by executing firmware loaded in Read-Only memory (ROM) of the memory controller 100.

The memory controller 100 may be configured to communicate with the host 20 through various standard interfaces. For example, the memory controller 100 may include the host interface 120, and the host interface 120 may be configured to provide various standard interfaces between the host 20 and the memory controller 100. The standard interfaces may include various interface schemes such as an Advanced Technology Attachment (ATA) interface, a Serial ATA (SATA) interface, an External SATA (e-SATA) interface, Small Computer Small Interface (SCSI), Serial Attached SCSI (SAS), a Peripheral Component Interconnect (PCI) card, a PCI Express (PCI-E) card, IEEE 1394, a Universal Serial Bus (USB), a Secure Digital (SD) card, a Multi-Media Card (MMC), an embedded Multi-Media Card (eMMC), a Universal Flash Storage (UFS), a Compact Flash (CF) card interface, and the like.

The host interface 120 may be configured to transmit/receive packets to/from the host 20. Packets transmitted from the host 20 to the host interface 120 may include commands, data to be written to the memory device, or the like, and packets transmitted from the host interface 120 to the host 20 may include responses to the commands, data read from the memory device, or the like.

The memory interface 130 may be configured to transmit, to the memory device 200, the data DATA to be written to the memory device 200, or receive the data DATA read from the memory device 200. The memory interface 130 may be implemented to conform to standard protocols such as Toggle or Open NAND Flash Interface (ONFI).

The memory device 200 may include a non-volatile memory device such as a flash memory. The flash memory may include a two-dimensional (2D) NAND memory array or a three-dimensional (3D) (or vertical) NAND (VNAND) memory array. In an embodiment, the 3D memory array includes vertical NAND strings arranged in a vertical direction such that at least one memory cell is on another memory cell. The at least one memory cell may include a charge trap layer.

The inventive concept is not limited thereto, and the memory device 200 may also include other various types of memory devices. For example, the memory device 200 may include a non-volatile memory, and various kinds of memory devices such as Magnetic RAM (MRAM), Spin-Transfer Torque MRAM, Conductive bridging RAM (CBRAM), Ferroelectric RAM (FeRAM), Phase RAM (PRAM), Resistive RAM (ReREAM), Nanotube RAM, Polymer RAM (PoRAM), Nano Floating Gate Memory (NFGM), holographic memory, Molecular Electronics Memory, Insulator Resistance Change Memory, or the like may be applied as the non-volatile memory. Hereinafter, the inventive concept will be described under the assumption that the memory device 200 includes or is a flash memory device.

The memory device 200 may include the memory cell array 210, the latch circuit 220, and the control logic 230. The memory cell array 210 may include a plurality of memory blocks. Each of the plurality of memory blocks may include a plurality of memory cells arranged in regions where a plurality of word lines cross a plurality of bit lines. In the memory cell array 210, erase operations with respect to the data may be performed in units of a block (e.g., a cell block), and program operations and read operations with respect to the data may be performed in units of a page.

Reference setting data rsd may be stored in the memory cell array 210. The reference setting data rsd may be stored initially in the memory cell array 210. At least some of memory cells in the memory cell array 210 may be configured to store important data such as setting data related to operation conditions of the memory system 10. The memory cell array 210 may include a memory block configured to store the reference setting data rsd. Setting data stored in the memory cell array 210 may be referred to as the reference setting data rsd. The setting data, i.e., data including information regarding setting operations of the memory device 200 used in a process of driving the memory system 10, may indicate information data read (IDR) data that is read for setting the operation conditions. For example, the setting data may include direct current (DC) information, option information, repair information, bad block information, and the like for the memory system 10.

The latch circuit 220 may include a plurality of latches. For example, the latch circuit 220 may include a plurality of electronic fuse (E-fuse) latches. However, the inventive concept is not limited thereto. In an initial driving process of the memory system 10, the latch circuit 220 may be configured to store the setting data. For example, when the memory system 10 is powered-on, the reference setting data rsd stored in the memory cell array 210 may be loaded and stored in the latch circuit 220 as load setting data lsd. The setting data stored in the latch circuit 220 may be referred to as the load setting data lsd.

The latch circuit 220 may be configured to store the load setting data lsd for operations of the memory cells, and the memory device 200 may be configured to set operations of the memory device 200 based on the load setting data lsd stored in the latch circuit 220. For example, the memory device 200 may be configured to set DC levels, verification voltage levels, and the like of the memory cells, based on the load setting data lsd.

When an error due to radiation occurs in the latch circuit 220, setting data different from the reference setting data rsd generated when designing the memory device 200 may be stored in the latch circuit 220. The error due to radiation may be a temporary error. When a temporary error occurs in the latch circuit 220, the load setting data stored in the latch circuit 220 may be different from the reference setting data rsd. For example, when a temporary error occurs in the latch circuit 220, operation environments for the memory cells may be set based on the load setting data lsd different from the reference setting data rsd. Accordingly, the memory cells may be respectively in different operation environments, and in read operations and write operations, data different from data received from the host 20 may be stored. That is, the reliability of the memory system 10 may be degraded.

Therefore, it is determined whether an error (e.g., a temporary error) has occurred in the latch circuit 220 and the load setting data lsd stored in the latch circuit 220 is recovered when the temporary error occurs. For example, the control logic 230 may be configured to determine whether an error has occurred in the latch circuit 220, and perform a recovery operation (e.g., load the reference setting data rds from the memory cell array 210 back to the latch circuit 220) when the temporary error occurs, to ensure that the load setting data lsd is identical to the reference setting data rsd. For example, the load setting data lsd stored in the latch circuit 220 may be entirely or partially overwritten by the reference setting data rsd when the temporary error is determined to have occurred.

The control logic 230 may be configured to control general operations of the memory device 200. For example, the control logic 230 may be configured to compare the reference setting data rds stored in the memory cell array 210 with the load setting data stored in the latch circuit 220. The control logic 230 may determine whether the reference setting data rds and the load setting data match. For example, the control logic 230 may include a comparator to compare the reference setting data rds with the load setting data lsd. When a temporary error has not occurred in the latch circuit 220, the load setting data lsd stored in the latch circuit 220 may match the reference setting data rsd.

When the load setting data lsd and the reference setting data rds match, the control logic 230 may determine that the temporary error has not occurred in the latch circuit 220. When the temporary occur has occurred in the latch circuit 220, the load setting data lsd stored in the latch circuit 220 does not match the reference setting data rsd. When the load setting data lsd and the reference setting data rsd do not match, the control logic 230 may determine that the temporary error has occurred in the latch circuit 220.

In an embodiment, the control logic 230 is configured to determine whether the load setting data and the reference setting data rsd match for each pair of bits. The load setting data and the reference setting data rsd may each include a plurality of bits. The control logic 230 may be configured to compare the reference setting data rsd with the load setting data lsd for each pair of bits. The control logic 230 may be configured to compare a bit value of a target bit among the plurality of bits of the load setting data lsd with a bit value of the reference setting data rsd corresponding to the target bit. Target bits may indicate bits to compare bit values thereof from among the plurality of bits of the load setting data and the reference setting data rsd.

For example, the control logic 230 may be configured to compare a bit value of a first bit of the load setting data lsd with a bit value of a first bit of the reference setting data rsd to determine whether the bit values match. The control logic 230 may be configured to compare a bit value of a second bit of the load setting data lsd with a bit value of a second bit of the reference setting data rsd to determine whether the bit values match.

The control logic 230 may be configured to determine a bit of the load setting data lsd, in which a bit value does not match the bit value of the reference setting data rsd, as an error bit. For example, among the plurality of bits of the load setting data lsd, the control logic 230 may be configured to determine a bit, in which the bit value does not match the bit value of the reference setting data rsd, as the error bit. For example, the control logic 230 may be configured to determine that the bit value of the first bit of the load setting data lsd and the bit value of the first bit of the reference setting data rsd match, and may also be configured to determine that the bit value of the second bit of the load setting data lsd and the bit value of the second bit of the reference setting data rsd do not match. The control logic 230 may be configured to determine the second bit of the load setting data lsd as the error bit. However, embodiments are not limited thereto.

The control logic 230 may be configured to control the recovery operation based on whether the reference setting data rsd and the load setting data lsd match. The recovery operation may indicate an operation of loading the reference setting data rsd from the memory cell array 210 back to the latch circuit 220. In an embodiment, when determining that the reference setting data lsd and the load setting data do not match, the control logic 230 may perform the recovery operation. The control logic 230 may be configured to control the memory cell array 210 and the latch circuit 220 to perform the recovery operation. The control logic 230 may be configured to load the reference setting data rsd from the memory cell array 210 back to the latch circuit 220 and store the load setting data lsd, which is identical to the reference setting data rsd, in the latch circuit 220. For example, the load setting data lsd that has been stored in the latch circuit 220 may be overwritten with the reference setting data rsd loaded from the memory cell array 210 through the recovery operation.

When at least one bit of the load setting data lsd is an error bit that does not match the reference setting data rsd, the load setting data stored in the latch circuit 220 may be different from the reference setting data rsd. Accordingly, the operation environments of the memory cells may be set based on the load setting data lsd different from the reference setting data rsd, and the memory cells may be respectively in different operation environments. When at least one of the bits of the load setting data lsd is an error bit, the control logic 230 may perform the recovery operation. Since the control logic 230 performs the recovery operation when there is an error bit in the load setting data lsd, the reliability of the load setting data may be increased, and the operation environments of the memory cells may be set based on the load setting data lsd that matches the reference setting data rsd.

In an embodiment, when the control logic 230 determines that the reference setting data rsd and the load setting data lsd match, the control logic 230 does not perform the recovery operation. For example, when all of the bits of the load setting data lsd match the reference setting data, the control logic 230 does not perform the recovery operation. When all of the bits of the reference setting data rsd match the load setting data lsd, the load setting data lsd does not include the error bit, and the load setting data lsd is identical to the reference setting data rsd. Accordingly, the operation environments of the memory cells may be set based on the load setting data lsd identical to the reference setting data rsd.

When the control logic 230 finds an error bit in the bits of the load setting data lsd, the control logic 230 may perform the recovery operation. In an embodiment, the control logic 230 is configured to compare the reference setting data rsd and the load setting data lsd for each pair of bits until the error bit is determined from among the bits of the load setting data lsd. When the error bit is determined, the control logic 230 may perform the recovery operation. The control logic 230 may be configured to compare the reference setting data rsd and the load setting data lsd until the error bit is determined, based on a preset orders of bits, and when the control logic 230 determines the error bit, the control logic 230 may immediately perform the recovery operation. The control logic 230 need not determine whether a bit of the load setting data lsd, which is posterior to the error bit that has been determined, matches the reference setting data rsd. For example, the control logic 230 need not check another bit after discovering one error bit.

During the error determination operation by the control logic 230 to determine whether the load setting data lsd and the reference setting data rsd match for each pair of bits, when the control logic 230 determines the error bit of the load setting data lsd, the control logic 230 may stop the error determination operation and perform the recovery operation with respect to the load setting data lsd. That is, when the control logic 230 finds an error bit in the load setting data, the control logic 230 may immediately perform the recovery operation.

In an embodiment, the control logic 230 compares bit values of all of the bits of the load setting data with bit values of all of the bits of the reference setting data rsd, and then performs the recovery operation when a result of the comparison indicates there is an error bit in the load setting data lsd. The control logic 230 may compare all of the bit values of the load setting data lsd and all of the bit values of the reference setting data rsd, and when at least one of the bits of the load setting data lsd is determined to be the error bit, the control logic 230 may perform the recovery operation. When the bits of the load setting data lsd do not include the error bit, the control logic 230 does not perform the recovery operation.

In the initial driving process of the memory system 10, the reference setting data rsd of the memory cell array 210 may be stored as the load setting data lsd in the latch circuit 220. In the initial driving process of the memory system 10, the memory device 200 may perform at least one of: the error determination operation to determine the error bit by determining whether the reference setting data rsd and the load setting data lsd match; and the recovery operation. For example, when the memory system 10 is switched from a powered-off state to a powered-on state, the memory system 10 may perform at least one of the error determination operation and the recovery operation.

However, embodiments of the disclosure are not limited thereto, and the memory device 200 may also perform the error determination operation and the recovery operation in a state where the memory system 10 is in a powered-on state. The memory device 200 may perform at least one of the error determination operation and the recovery operation when the memory system 10 is powered-on, and may also repeatedly perform at least one of the error determination operation and the recovery operation after a preset time period from a time point when the memory system 10 is powered-on.

For example, the memory device 200 may perform at least one of the error determination operation and the recovery operation in an idle state. The idle state may indicate a state in which the memory device 200 does not perform memory operations such as write operations and read operations. For example, the memory device 200 may perform at least one of the error determination operation and the recovery operation when the memory system 10 is powered-on, and may perform at least one of the error determination operation and the recovery operation each time the memory device 200 is in the idle state. The memory device 200 may periodically confirm whether an error has occurred in the latch circuit 220.

When the memory system 10 is powered-on, the control logic 230 may identify whether a temporary error has occurred in the latch circuit 220 by determining whether the reference setting data rsd and the load setting data lsd match. When the reference setting data rsd and the load setting data lsd do not match to indicate the temporary error has occurred, the control logic 230 may perform the recovery operation. In an embodiment, after a preset time period from the recovery operation, the control logic 230 may determine again whether a temporary error has occurred in the latch circuit 220, and may stop the recovery operation when the temporary error has again occurred in the latch circuit 220.

The control logic 230 may determine a permanent error of the latch circuit 220. The permanent error may indicate that the latch circuit 220 is damaged, unlike the temporary error in which the load setting data lsd stored in the latch circuit 220 becomes different from the reference setting data due to external environments, radiation, and the like. The temporary error may be overcome through the recovery operation, but it may be difficult to overcome the permanent error through the recovery operation. When determining that the permanent error has occurred in the latch circuit 220, the control logic 230 may stop the recovery operation.

The control logic 230 may perform the error determination operations with a certain time interval, and when the error bit is determined in all of error determination operations consecutively performed twice or more, the control logic 230 may determine that the permanent error has occurred in the latch circuit 220. For example, the control logic 230 may perform the error determination operation periodically. After determining that the temporary error has occurred in the latch circuit 220 and performing the recovery operation, the control logic 230 may compare the reference setting data rsd with the load setting data lsd after a preset time period and determine again whether the temporary error has occurred in the latch circuit 220. When the reference setting data rsd and the load setting data lsd do not match and the temporary error has again occurred in the latch circuit 220, the control logic 230 may determine that the permanent error has occurred in the latch circuit 220. In an embodiment, when the permanent error is determined to have occurred in the latch circuit 220, the control logic 230 does not perform the recovery operation.

The memory device 200 according to an embodiment of the inventive concept determines whether the reference setting data rsd stored in the memory cell array 210 and the load setting data lsd stored in the latch circuit 220 match in the memory device 200, and when the reference setting data rsd and the load setting data lsd do not match, the memory device 200 performs an operation of recovering the load setting data lsd, to thereby perform the error determination operations and the recovery operations with respect to the setting data at an increased rate. In addition, when an error occurs in the latch circuit 220 and the load setting data lsd becomes different from the reference setting data rsd, by performing the recovery operation, the reliability of the load setting data lsd may be increased, and the operation environments of the memory system 10 may be stably managed.

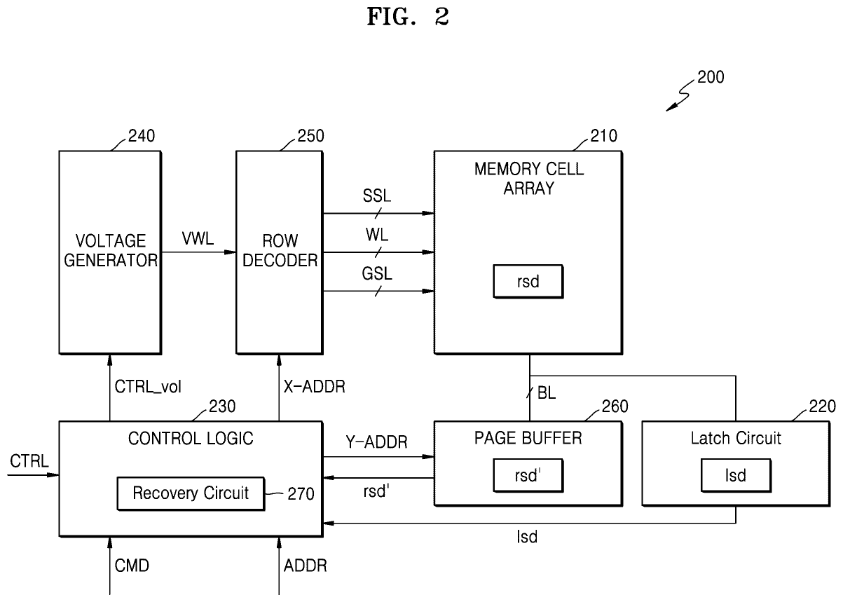

FIG. 2 is a diagram for describing the memory device 200 according to an embodiment. Since the memory device 200, the memory cell array 210, the latch circuit 220, and the control logic 230 illustrated in FIG. 2 respectively correspond to the memory device 200, the memory cell array 210, the latch circuit 220, and the control logic 230 illustrated in FIG. 1, same descriptions as those with reference to FIG. 1 will not be given.

Referring to FIG. 2, the memory device 200 includes the memory cell array 210, the latch circuit 220, the control logic 230, a voltage generator 240, a row decoder 250 (e.g., a decoder circuit), and a page buffer 260.

The memory cell array 210 may include a plurality of memory cells, and may be connected to word lines WL, string selection lines SSL, ground selection lines GSL, and a plurality of bit lines BL. More particularly, the memory cell array 210 may be connected to the row decoder 250 through the word lines WL, the string selection lines SS, and the ground selection lines GSL, and may be connected to the page buffer 260 through the plurality of bit lines BL.

The memory cell array 210 may include a plurality of memory blocks, and for example, each of the plurality of memory blocks may include a plurality of memory cells. Each of the plurality of memory blocks may have a three-dimensional structure (or a vertical structure). The plurality of memory blocks may be selected by the row decoder 250. For example, the row decoder 250 may be configured to select a memory block corresponding to a block address from among the plurality of memory blocks. The memory cell array 210 may be configured to store the reference setting data rsd, as described with reference to FIG. 1.

The control logic 230 may be configured to control various operations in the memory device 200. For example, the control logic 230 may be configured to output various kinds of control signals for writing data to the memory cell array 210 or read data from the memory cell array 210, based on commands CMD, addresses ADDR, and control signals CTRL. For example, the control logic 230 may be configured to output a voltage control signal CTRL_vol, a row address X-ADD, and a column address Y-ADD. The control logic 230 may also be configured to output control signals to read setting data from the page buffer 260 and the latch circuit 220.

Various kinds of control signals output from the control logic 230 may be provided to the voltage generator 240, the row decoder 250, the latch circuit 220, and the page buffer 260. The control logic 230 may be configured to provide the voltage control signal CTRL_vol to the voltage generator 240.

In some embodiments, the control logic 230 may include a recovery circuit 270. The recovery circuit 270 may be configured to perform error determination operations to determine whether an error has occurred in the latch circuit 220, and may perform recovery operations to recover data of the load setting data lsd found to be in error. The recovery circuit 270 may be configured to determine whether the error has occurred in the latch circuit 220 through the error determination operation to determine whether the reference setting data rsd and the load setting data lsd match. When it is determined that the temporary error has occurred in the latch circuit 220, the recovery circuit 270 may perform the recovery operation. Although FIG. 2 illustrates that the recovery circuit 270 is included in the control logic 230, the recovery circuit 270 is not limited thereto and may be separate from the control logic 230.

The voltage generator 240 may be configured to generate various kinds of voltages to perform program, read, and write operations with respect to the memory cell array 210, based on the voltage control signal CTRL_vol. Particularly, the voltage generator 240 may be configured to generate a word line voltage VWL, for example, a program voltage, a read voltage, an erase voltage, and the like. For example, in a read operation, the voltage generator 240 may generate a read voltage and provide the read voltage to the row decoder 250, under control of the control logic 230. In addition, the voltage generator 240 may be configured to further generate a string selection line voltage and a ground selection line voltage, based on the voltage control signal CTRL_vol.

The row decoder 250 may select a particular word line from among the word lines WL, in response to the row address X-ADDR received from the control logic 230. For example, in the read operation, the row decoder 250 may provide the read voltage to the word line that has been selected. In addition, the row decoder 250 may select some of the string selection lines SSL or some of the ground selection lines GSL, in response to the row address X-ADDR received from the control logic 230.

The page buffer 260 may be connected to the memory cell array 210 through the plurality of bit lines BL. The page buffer 260 may be configured to select some of the plurality of bit lines BL in response to the column address Y-ADDR received from the control logic 230. The page buffer 260 may be configured to temporarily store data read from the memory cell array 210 or data to be stored in the memory cell array 210.

The page buffer 260 may include a plurality of page buffers respectively connected to the plurality of bit lines BL. The plurality of page buffers may be arranged to correspond to respective bit lines, and each of the page buffers may include a plurality of latches. Hereinafter, it will be described that the page buffer 260 includes page buffers connected to the respective bit lines. However, the embodiments may be different. For example, a page buffer may be provided to correspond to a plurality of bit lines, and a unit of a configuration arranged to correspond to each of the plurality of bit lines may be defined as a page buffer unit.

In an embodiment, reference setting data rsd′ is stored in the page buffer 260. Before the recovery circuit 270 performs the error determination operation, the reference setting data rsd stored in the memory cell array 210 may be loaded and stored in the page buffer 260 as reference setting data rsd′. The reference setting data rsd′ stored in the page buffer 260 may be identical to the reference setting data rsd stored in the memory cell array 210. For example, when the memory device 200 is powered-on, the reference setting data rsd stored in the memory cell array 210 may be loaded to the page buffer 260, and the recovery circuit 270 may perform the error determination operation.

In an embodiment, the latch circuit 220 includes a plurality of latches. For example, the latch circuit 220 may include a plurality of E-fuse latches. However, the inventive concept is not limited thereto. The latch circuit 220 may be configured to store the setting data.

Before the recovery circuit 270 performs the error determination operation, the reference setting data rsd stored in the memory cell array 210 may be loaded to the latch circuit 220 and stored as the load setting data lsd. For example, when the memory device 200 is powered-on, the reference setting data rsd stored in the memory cell array 210 may be loaded and stored in the latch circuit 220 as the load setting data lsd. The setting data stored in the latch circuit 220 may be referred to as the load setting data lsd. The memory device 200 may be configured to set operations of the memory device 200 based on the load setting data lsd stored in the latch circuit 220. When an error occurs in the latch circuit 220, the load setting data lsd may become different from the reference setting data rsd.

The recovery circuit 270 may be configured to determine whether the reference setting data rsd′ and the load setting data lsd match. The recovery circuit 270 may be configured to receive the reference setting data rsd′ from the page buffer 260, receive the load setting data lsd from the latch circuit 220, and compare the reference setting data rsd′ with the load setting data lsd.

When the load setting data lsd output from the latch circuit 220 and the reference setting data rsd′ output from the page buffer 260 match, the recovery circuit 270 determines that a temporary error has not occurred in the latch circuit 220. When the load setting data lsd and the reference setting data rsd′ do not match, the recovery circuit 270 may determine that a temporary error has occurred in the latch circuit 220.

The recovery circuit 270 may be configured to determine whether the load setting data lsd and the reference setting data rsd′ match for each bit. From among the bits of the load setting data lsd, the recovery circuit 270 may determine a bit, in which a bit value of the load setting data lsd and a bit value of the reference setting data rsd′ do not match, as the error bit.

The recovery circuit 270 may be configured to control the recovery operation based on whether the reference setting data rsd′ and the load setting data lsd match. The recovery operation may indicate an operation of loading the reference setting data rsd stored in the memory cell array 210 back to the latch circuit 220. In an embodiment, when it is determined that the reference setting data rsd′ and the load setting data lsd do not match, the recovery circuit 270 may perform the recovery operation. For example, the recovery circuit 270 may overwrite the load setting data lsd stored in the latch circuit 220 with the reference setting data rsd stored in the memory cell array 210 when it is determined that the reference setting data rsd′ and the load setting data lsd do not match.

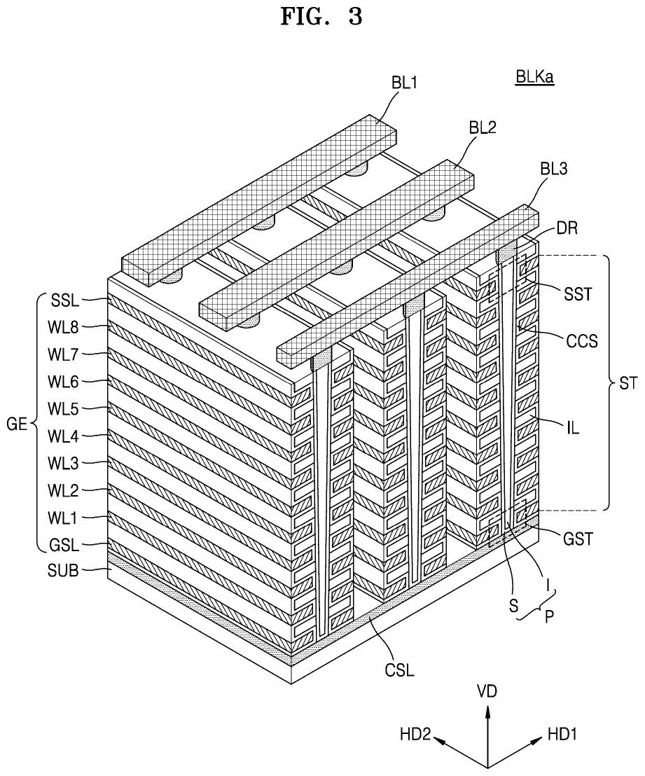

FIG. 3 is a perspective view of a memory block BLKa according to an embodiment.

Referring to FIG. 3, the memory block BLKa may include a stack ST extending in a vertical direction VD on a substrate SUB. For example, the memory block BLKa may include a single stack ST disposed between the substrate SUB and bit lines (i.e., a first bit line BL1, a second bit line BL2, and a third bit line BL3). Common source lines CSL may be disposed on the substrate SUB, insulating films IL extending in a second horizontal direction HD2 may be sequentially arranged on the substrate SUB and the common source lines CSL in a vertical direction VD, and the insulating films IL may be spaced apart from each other by a certain distance in the vertical direction VD. Pillars P penetrating the insulating films IL in the vertical direction VD are disposed on the substrate SUB and the common source lines CSL. The pillars P may be referred to as channel holes. The pillars P may be formed in a cup shape (or a bottom-closed cylinder shape) extending in the vertical direction VD. A surface layer S of each of the pillars P may include a silicon material of a first type, and may function as a channel region. An internal layer I of each of the pillars P may include an insulating material, e.g., silicon oxide, or air gaps.

A charge storage layer CCS is disposed along exposed surfaces of the insulating films IL, the pillars P, and the substrate SUB. The charge storage layer CCS may include a gate insulating layer, a charge trap layer, and a blocking insulating layer. For example, the charge storage layer CCS may have an oxide-nitride-oxide (ONO) structure. In addition, on the exposed surface of the charge storage layer CCS, gate electrodes GE such as selection lines (i.e., the ground selection lines GSL and the string selection lines SSL) and word lines (i.e., a first word line WL1, a second word line WL2, a third word line WL3, a fourth word line WL4, a fifth word line W5, a sixth word line W6, a seventh word line W7, and an eighth word line WL8) may be disposed. Drains DR are respectively disposed on the plurality of pillars P. The bit lines (i.e., the first bit line BL1, the second bit line BL2, and the third bit line BL3) extending in a first horizontal direction HD1 and arranged spaced apart from one another by a certain distance in the second horizontal direction HD2 are disposed on the drains DR.

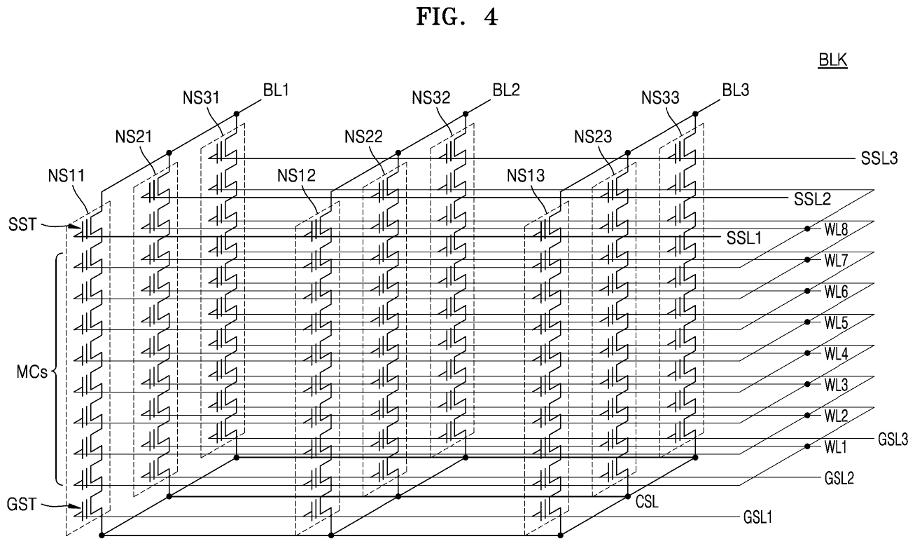

FIG. 4 is a circuit diagram of a memory block BLK according to an embodiment.

Referring to FIG. 4, the memory block BLK may include NAND strings NS11 to NS33, and each of the NAND strings (e.g., the NAND string NS11) may include a string selection transistor SST, a plurality of memory cells MCs, and a ground selection transistor GST connected in series. Transistors (i.e., the string selection transistor SST and the ground selection transistor GST) and the memory cells MCs included in each NAND string may form a structure stacked in the vertical direction on the substrate.

The bit lines BL1 to BL3 may extend in a first direction, and the word lines WL1 to WL8 may extend in a second direction. The NAND strings NS11, NS21, and NS31 may be disposed between the first bit line BL1 and the common source line CSL. The NAND strings NS12, NS22, and NS32 may be disposed between the second bit line BL2 and the common source line CSL. The NAND strings NS13, NS23, and NS33 may be disposed between the third bit line BL3 and the common source line CSL.

The string selection transistors SST may be connected to corresponding string selection lines SSL1 to SSL3. The plurality of memory cells MCs may be respectively connected to corresponding word lines WL1 to WL8. The ground selection transistors GST may be connected to corresponding grounding selection lines GSL1 to GSL3. The string selection transistors SST may be connected to corresponding bit lines, and the ground selection transistors GST may be connected to the common source line CSL. Here, the number of NAND strings, the number of word lines, the number of bit lines, the number of ground selection lines, and the number of string selection lines may be variously modified according to embodiments.

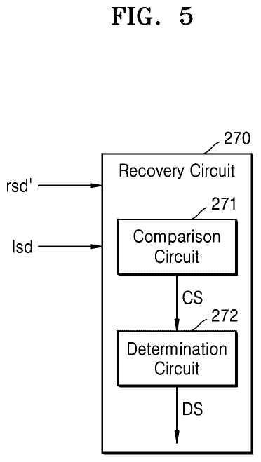

FIG. 5 is a block diagram for describing the recovery circuit 270 according to an embodiment. Same descriptions as those provided above will not be given.

Referring to FIG. 5, the recovery circuit 270 includes a comparison circuit 271 (e.g., one or more comparators) and a determination circuit 272 (e.g., a logic circuit). The recovery circuit 270 may be configured to receive the load setting data lsd from a latch circuit (e.g., the latch circuit 220 illustrated in FIG. 2) and receive the reference setting data rsd′ from a page buffer (e.g., the page buffer 260 illustrated in FIG. 2).

The comparison circuit 271 may be configured to receive the reference setting data rsd′ and the load setting data lsd. The comparison circuit 271 may be configured to output a comparison signal CS by comparing the reference setting data rsd′ with the load setting data lsd.

The comparison circuit 271 may be configured to compare the load setting data lsd with the reference setting data rsd′ for each pair of bits. The comparison circuit 271 may be configured to determine whether the load setting data lsd and the reference setting data rsd′ match for each pair of bits and output the comparison signal CS for each pair of bits. For example, the comparison circuit 271 may be configured to compare a bit value of a first bit of the load setting data lsd with a bit value of a first bit of the reference setting data rsd′ to determine a result for the first bits and output a comparison signal CS based or indicating the result for the first bits.

The comparison circuit 271 may be configured to perform the error determination operations according to orders of bits of the load setting data lsd received by the comparison circuit 271 among the bits of the load setting data lsd and output a comparison signal CS for each bit. For example, it is assumed that the first bit and the second bit of the load setting data lsd are sequentially input to the comparison circuit 271. The comparison circuit 271 may be configured to determine whether the bit values of the first bit of the load setting data lsd and the first bit of the reference setting data rsd′ match and output a comparison signal CS for the first bit of the load setting data lsd. After outputting the comparison signal CS for the first bit of the load setting data lsd, the comparison circuit 271 may determine whether the bit value of the second bit of the load setting data lsd and the bit value of the second bit of the reference setting data rsd′ match and output a comparison signal CS for the second bit of the load setting data lsd.

In an embodiment, when the reference setting data rsd′ and the load setting data lsd match, the comparison circuit 271 outputs a comparison signal CS having a first comparison value. For example, when the bit value of the first bit of the load setting data lsd and the bit value of the first bit of the reference setting data rsd′ match, the comparison circuit 271 may output the comparison signal CS having the first comparison value.

In an embodiment, when the reference setting data rsd′ and the load setting data lsd do not match, the comparison circuit 271 output a comparison signal CS having a second comparison value. For example, when the bit value of the second bit of the load setting data lsd and the bit value of the second bit of the reference setting data rsd′ do not match, the comparison circuit 271 may output the comparison signal CS having the second comparison value. For example, the second bit of the load setting data lsd may include or be the error bit.

The first comparison value and the second comparison value are different from each other. For example, the first comparison value may be 0, and the second comparison value may be 1. However, embodiments are not limited thereto. For example, the first comparison value may be 1, and the second comparison value may be 0. The comparison circuit 271 may output the comparison signal CS for each bit.

In an embodiment, the comparison circuit 271 includes an XOR gate configured to output comparison signals CS based on a first input and a second input. The XOR gate may be configured to receive the first input and the second input to output the comparison signals CS. For example, the first input may include or be the reference setting data rsd′, and the second input may include or be the load setting data lsd. When the first input and the second input are identical to each other, the XOR gate may output a comparison signal CS having the value of 0. On the other hand, when the first input and the second input are not identical to each other, the XOR gate may output a comparison signal CS having the value of 1.

The determination circuit 272 may control the recovery operation based on the comparison signals CS. The determination circuit 272 may generate determination signals DS to control the recovery operation, based on the comparison signals CS. In an embodiment, upon receiving the comparison signal CS having the second comparison value, the determination circuit 272 may generate a determination signal DS for performing the recovery operation. Upon the comparison signal CS having the first comparison value, the determination circuit 272 may generate a determination signal DS for not performing the recovery operation.

Upon receiving the comparison signal CS having the second comparison value, the determination circuit 272 may generate a determination signal DS including a first determination value for performing the recovery operation. In an embodiment, upon receiving the comparison signal CS having the second comparison value, the determination circuit 272 may immediately generate the determination signal DS including the first determination value. For example, when the comparison signal CS received for the second bit of the load setting data lsd is the second comparison value, the determination circuit 272 may immediately generate the determination signal DS including the first determination value.

The recovery operation may be controlled based on the determination signal DS. The recovery operation may be performed with respect to the load setting data lsd, based on the determination signal DS having the first determination value. For example, based on the determination signal DS, a memory cell array (e.g., the memory cell array 210 shown in FIG. 2) and a latch circuit (e.g., the latch circuit 220 shown in FIG. 2) may be controlled to perform the recovery operation. Based on the determination signals DS, the reference setting data of the memory cell array may be loaded back in the latch circuit and stored as the load setting data lsd.

Upon receiving the comparison signals CS having the first comparison value, the determination circuit 272 may generate a determination signal DS including a second determination value for not performing the recovery operation. Upon receiving the comparison signal CS having the first comparison value, the determination circuit 272 may generate the determination signal DS including the second determination value. For example, when the comparison signals CS received for the first bit of the load setting data lsd is the first comparison value, the determination circuit 272 may generate the determination signal DS including the second determination value. Based on the determination signal DS having the second determination value, the recovery operation may be not performed with respect to the load setting data lsd.

In an embodiment, the first determination value and the second determination value are different from each other. For example, the first determination value may be 1, and the second determination value may be 0. However, embodiments are not limited thereto. For example, instead, the first determination value may be 0, and the second determination value may be 1.

In an embodiment, the comparison circuit 271 compares all bits of reference setting data rsd′ with the load setting data lsd to determine whether all bits match or which of the bits do not match, and the comparison circuit 271 outputs a single signal including first information when all bits match or second information when one of the bits does not match. The first information may indicate all bits match. The second information may indicate which of the bits do not match and/or there is an error (e.g., a temporary error). In this embodiment, the determination circuit 272, does not perform a recovery operation when it receives the first information, but performs a recovery operation when it receives the second information.

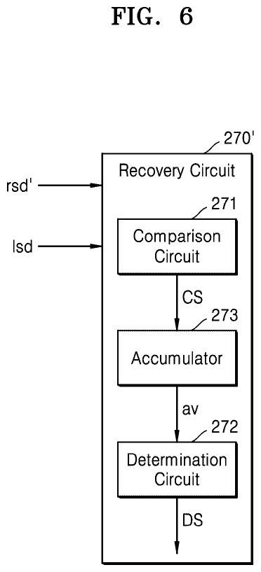

FIG. 6 is a diagram an embodiment of the recovery circuit 270 of FIG. 2 that differs from that shown in FIG. 5. A recovery circuit 270′ illustrated in FIG. 6 may further include an accumulator 273 in addition to the recovery circuit 270 illustrated in FIG. 5. Same descriptions as those provided above will not be given.

Referring to FIG. 6, the recovery circuit 270′ includes the comparison circuit 271, the accumulator 273, and the determination circuit 272. The recovery circuit 270 may be configured to receive the load setting data lsd from a latch circuit (e.g., the latch circuit 220 illustrated in FIG. 2) and receive the reference setting data rsd′ from a page buffer (e.g., the page buffer 260 illustrated in FIG. 2).

The comparison circuit 271 may be configured to receive the reference setting data rsd′ and the load setting data lsd. The comparison circuit 271 may be configured to output a comparison signal CS by comparing the reference setting data rsd′ with the load setting data lsd. The comparison circuit 271 may be configured to determine whether the load setting data lsd and the reference setting data rsd′ match for each pair of bits to output the comparison signal CS for each pair of bits.

The accumulator 273 may be configured to generate an accumulation value av by accumulating comparison values of the comparison signal CS. In an embodiment, the accumulator 273 may be configured to generate the accumulated value av by accumulating comparison values of the comparison signals for every bit of the load setting data lsd. For example, when the load setting data lsd has N bits (where N is a positive integer), the accumulator 273 may generate the accumulation value av by accumulating comparison values of the comparison signals CS for respective N bits.

When a temporary error has not occurred in the latch circuit (e.g., the latch circuit 220 shown in FIG. 2), bit values of all of the bits of the load setting data lsd may match the reference setting data rsd′. In this case, the accumulator 273 may only receive the comparison signals CS having the first comparison values for all of the bits of the load setting data lsd, and may generate an accumulation value av obtained by accumulation of the first comparison values. For example, when the first comparison value is 0, the accumulation value av may be 0.

When a temporary error has occurred in the latch circuit, at least one bit value of all of the bits of the load setting data lsd may not match the reference setting data rsd′. In this case, the accumulator 273 may receive the comparison signal CS having the second comparison value for at least one of the bits of the load setting data lsd. The accumulator 273 may receive the comparison signal CS having the first comparison value and the comparison signal CS having the second comparison value. The accumulator 273 may be configured to generate an accumulation value av obtained by accumulating the first comparison values and the second comparison values. For example, when the first comparison value is 0 and the second comparison value is 1, the accumulation value av may have a value equal to 1 or greater.

The determination circuit 272 may control the recovery operation based on the accumulation value av. The determination circuit 272 may generate the determination signal DS for controlling the recovery operation, based on the accumulation value av. For example, when the accumulation value av is greater than a reference accumulation value, the determination circuit 272 may generate the determination signal DS for performing the recovery operation. For example, when the accumulation value av is greater than the reference accumulation value, the determination circuit 272 may generate the determination signal DS including the first determination value for performing the recovery operation.

When the accumulation value av is less than or equal to the reference accumulation value, the determination circuit 272 may generate the determination signal DS for not performing the recovery operation. For example, when the accumulation value av is less than or equal to the reference accumulation value, the determination circuit 272 may generate the determination signal DS including the second determination value for not performing the recovery operation.

The load setting data lsd may include N bits of data. In an embodiment, the accumulator 273 generates a sub-accumulation value by accumulating k times (where k is a positive integer of N binominal) the comparison value of the comparison signal CS. For example, when the load setting data lsd includes N bits (where N is a positive integer), the accumulator 273 may generate the sub-accumulation value by accumulating comparison values of the comparison signals CS for respective k bits.

The determination circuit 272 may control the recovery operation based on the sub-accumulation value. The determination circuit 272 may generate the determination signal DS to control the recovery operation, based on the sub-accumulation value. For example, when the sub-accumulation value is greater than the reference accumulation value, the determination circuit 272 may generate the determination signal DS for performing the recovery operation. For example, when the sub-accumulation value is greater than the reference accumulation value, the determination circuit 272 may generate the determination signal DS including the first determination value for performing the recovery operation.

When the sub-accumulation value is less than or equal to the reference accumulation value, the determination circuit 272 may generate the determination signal DS for not performing the recovery operation. For example, when the sub-accumulation value is equal to the reference accumulation value or less, the determination circuit 272 may generate the determination signal DS including the second determination value for not performing the recovery operation.

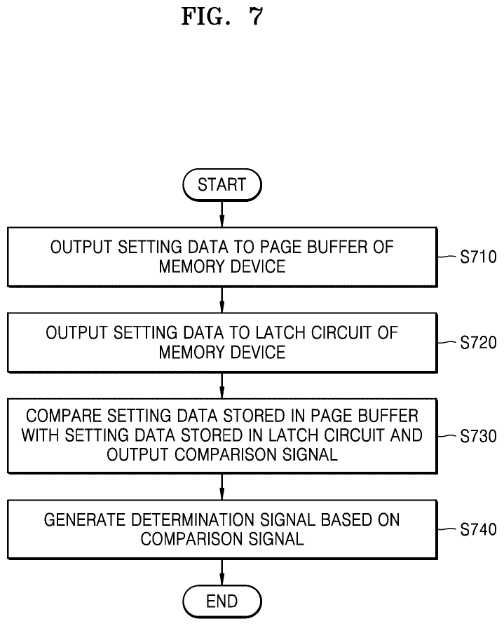

FIG. 7 is a flowchart for describing an operating method of the memory device, according to an embodiment. The operating method of the memory device 200 illustrated in FIG. 2 is described with reference to FIG. 7. More particularly, FIG. 7 illustrates an operating method of the control logic 230. Hereinafter, description will be given with reference to FIGS. 2 and 7 together. Same descriptions as those provided above will not be given.

In operation S710, the control logic 230 outputs the setting data from the memory cell array 210 to the page buffer 260 of the memory device 200. The setting data, i.e. data including information regarding the setting operations of the memory device 200 in the process of driving the memory system 10, may indicate IDR data read for setting the operation conditions. The setting data stored in the memory cell array 210 may be referred to as the reference setting data rsd.

The reference setting data rsd may be output from the memory cell array 210 for storage in the page buffer 260. Before the control logic 230 performs the error determination operation, the reference setting data rsd stored in the memory cell array 210 may be loaded and stored in the page buffer 260 as reference setting data rsd′. The reference setting data rsd′ loaded to the page buffer 260 may be equal to the reference setting data rsd stored in the memory cell array 210. For example, when the memory device 200 is powered-on, the reference setting data rsd stored in the memory cell array 210 may be loaded to the page buffer 260 as reference setting data rsd′. The page buffer 260 may be configured to store the reference setting data rsd′.

In operation S720, the control logic 230 outputs the setting data from the memory cell array 210 to the latch circuit 220. The latch circuit 220 may include the plurality of latches. For example, the latch circuit 220 may include the plurality of E-fuse latches. However, the inventive concept is not limited thereto. The latch circuit 220 may be configured to store the setting data. The reference setting data rsd may be loaded in the latch circuit 220 and stored as the load setting data lsd. The setting data stored in the latch circuit 220 may be referred to as the load setting data lsd.

Before the control logic 230 performs the error determination operation, the reference setting data rsd stored in the memory cell array 210 may be loaded to the latch circuit 220 and stored as the load setting data lsd. For example, when the memory device 200 is powered-on, the reference setting data rsd stored in the memory cell array 210 may be loaded and stored in the latch circuit 220 as the load setting data lsd.

Although FIG. 7 illustrates that operation S710 occurs prior to operation S720, embodiments are not limited thereto. Operation S710 may be posterior to operation S720, and operations S710 and S720 may be simultaneously performed.

In operation S730, the control logic 230 compares setting data stored in the page buffer 260 with setting data stored in the latch circuit 220 to generate a result, and outputs a comparison signal based on or including the result. That is, the control logic 230 may compare the reference setting data rsd′ with the load setting data lsd to output the comparison signal. The control logic 230 may be configured to determine whether the reference setting data rsd′ and the load setting data lsd match.

When the load setting data lsd and the reference setting data rsd′ output from the page buffer 260 match, the control logic 230 may determine that a temporary error has not occurred in the latch circuit 220. When the load setting data lsd and the reference setting data rsd′ output from the page buffer 260 do not match, the control logic 230 may determine that a temporary error has occurred in the latch circuit 220.

In an embodiment, when the reference setting data rsd′ and the load setting data lsd match, the control logic 230 may output the comparison signal having the first comparison value. When the reference setting data rsd′ and the load setting data lsd do not match, the control logic 230 may output the comparison signal having the second comparison value. The first comparison value and the second comparison value are different from each other. For example, the first comparison value may be 0, and the second comparison value may be 1. However, the embodiments are limited thereto. For example, the first comparison value may be 1, and the second comparison value may be 0.

In operation S740, the control logic 230 generates a determination signal based on the comparison signal. The determination signal may include a signal for controlling the recovery operation. The recovery operation may indicate an operation of loading the reference setting data rsd from the memory cell array 210 back to the latch circuit 220. In an embodiment, when the control logic 230 determines that the reference setting data rsd′ and the load setting data lsd do not match, the control logic 230 may perform the recovery operation. The control logic 230 may load the reference setting data rsd from the memory cell array 210 back to the latch circuit 220, thereby storing the load setting data lsd matching the reference setting data rsd to the latch circuit 220. In an embodiment, the control logic 230 overwrites all of the load setting data lsd stored in the latch circuit 220 with all of the reference setting data rsd from the memory cell array 210, when the reference setting data rsd′ and the load setting data lsd do not match. In an embodiment, when only one or some bits of the load setting data lsd has an error, the control logic 230 overwrites only the corresponding one or some bits with corresponding bit(s) of the reference setting data rsd and maintains the remaining bit(s) of the load setting data lsd.

In an embodiment, when the control logic 230 determines that the reference setting data rsd′ and the load setting data lsd match, the control logic 230 does not perform the recovery operation. For example, when every bit of the load setting data lsd matches the reference setting data rsd′, the control logic 230 does not perform the recovery operation. Accordingly, the operation environments of the memory cells may be set based on the load setting data lsd identical to the reference setting data rsd.

The memory device 200 may determine whether the reference setting data rsd (e.g., the reference setting data rsd′ stored in the page buffer 260) stored in the memory cell array 210 and the load setting data lsd stored in the latch circuit 220 match in the memory device 200, and when the reference setting data rsd and the load setting data lsd do not match, the memory device 200 may perform an operation of recovering the load setting data lsd, to thereby perform the error determination operation and the recovery operation of the latch circuit 220 at an increased rate. Accordingly, the reliability of the setting data may be increased, and the operation environments of the memory system may be stably managed.

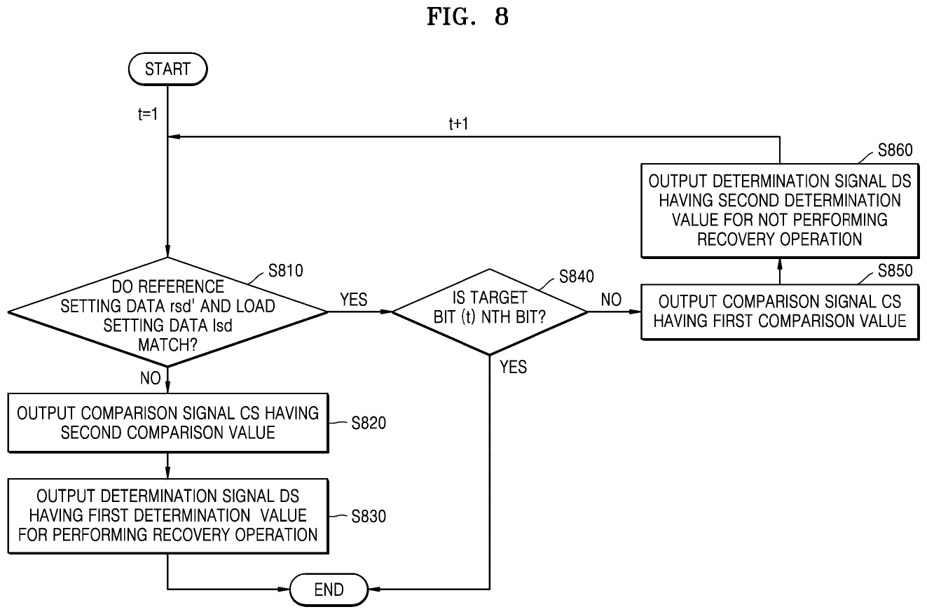

FIG. 8 is a flowchart for describing an operating method of the recovery circuit, according to an embodiment. More particularly, FIG. 8 illustrates the operating method of the recovery circuit 270 illustrated in FIG. 5. The operating method illustrated in FIG. 8 may be performed in operations S730 and S740 illustrated in FIG. 7. Operations S710 and S720 in FIG. 7 may be performed before operation S810 shown in FIG. 8. Same descriptions as those provided above will not be given.

Referring to FIGS. 5 and 8, the recovery circuit 270 may compare the load setting data lsd and the reference setting data rsd′ for each pair of bits. The comparison circuit 271 may be configured to determine whether the load setting data lsd and the reference setting data rsd′ match for each pair of bits and output the comparison signal CS for each pair of bits. In FIG. 8, it is assumed that the load setting data lsd includes N (where N is a positive integer) bits, and for example, the error determination operations may be sequentially performed from a first bit to an Nth bit. Operation S810 may be performed from a case where a target bit t is the first bit. The target bit t may indicate a bit being a target of the error determination operation among the plurality of bits of the load setting data lsd.

In operation S810, the recovery circuit 270 determines whether the reference setting data rsd′ and the load setting data lsd match. When the target bit t is the first bit, the comparison circuit 271 may compare the bit value of the first bit of the load setting data lsd and the bit value of the first bit of the reference setting data rsd′ to generate a result and determine whether the bit value of the first bit of the load setting data lsd and the bit value of the first bit of the reference setting data rsd′ match based on the result. The comparison circuit 271 may perform operation S820 when the reference setting data rsd′ and the load setting data lsd do not match, and may perform operation S840 when the reference setting data rsd′ and the load setting data lsd match.

In operation S820, when the reference setting data rsd′ and the load setting data lsd do not match, the recovery circuit 270 outputs the comparison signal CS having the second comparison value. For example, when the bit value of the first bit of the load setting data lsd and the bit value of the first bit of the reference setting data rsd′ do not match, the comparison circuit 271 may output the comparison signal CS having the second comparison value. The first bit of the load setting data lsd may include the error bit.

In operation S830, the recovery circuit 270 outputs the determination signal DS having the first determination value. The determination circuit 272 may generate the determination signal DS to control the recovery operation, based on the comparison signal CS. Upon receiving the comparison signal CS having the second comparison value, the determination circuit 272 may generate the determination signal DS for performing the recovery operation.

Upon receiving the comparison signal CS having the second comparison value, the determination circuit 272 may generate the determination signal DS including the first determination value for performing the recovery operation. For example, when the comparison signal CS received for the first bit of the load setting data lsd includes the second comparison value, the determination circuit 272 may immediately generate the determination signal DS including the first determination value for the first bit. The recovery operation may be controlled based on the determination signal DS. The recovery operation may be performed with respect to the load setting data lsd, based on the determination signal DS having the first determination value.

In operation S840, when the reference setting data rsd′ and the load setting data lsd match, the recovery circuit 270 may confirm whether the target bit t is the Nth bit. When the target bit t is not the Nth bit, the recovery circuit 270 may perform operation S850. That is, when the target bit t is not the Nth bit, i.e., a last bit among the N bits of the load setting data lsd, the recovery circuit 270 may perform operation S850.

In operation S850, when the reference setting data rsd′ and the load setting data lsd match and the target bit t is not the Nth bit, the recovery circuit 270 outputs the comparison signal CS having the first comparison value. For example, when the bit value of the first bit of the load setting data lsd and the bit value of the first bit of the reference setting data rsd′ match, the comparison circuit 271 may output the comparison signal CS having the first comparison value.

In operation S860, the recovery circuit 270 outputs the determination signal DS having the second determination value. The determination circuit 272 may generate the determination signal DS to control the recovery operation, based on the comparison signal CS. Upon receiving the comparison signal CS having the first comparison value, the determination circuit 272 may generate the determination signals DS for not performing the recovery operation.

Upon receiving the comparison signal CS having the first comparison value, the determination circuit 272 may generate the determination signal DS including the second determination value for not performing the recovery operation. For example, when the comparison signal CS received for the first bit of the load setting data lsd includes the first comparison value, the determination circuit 272 may immediately generate the determination signal DS including the second determination value for the first bit. Based on the determination signal DS having the second determination value, the recovery operation may be not performed with respect to the load setting data lsd, and the error determination operation may be performed again from operation S810 on the following target bit t. For example, upon outputting the determination signal DS having the second determination value for the first bit in operation S860, the error determination operation may be performed again from operation S810 with respect to the second bit.

In some embodiments, the error determination operation may also be performed with respect to m bits at once among N bits of the load setting data lsd. The number of target bits may be m, and the recovery circuit 270 may also generate the comparison signal CS for each of the m target bits.

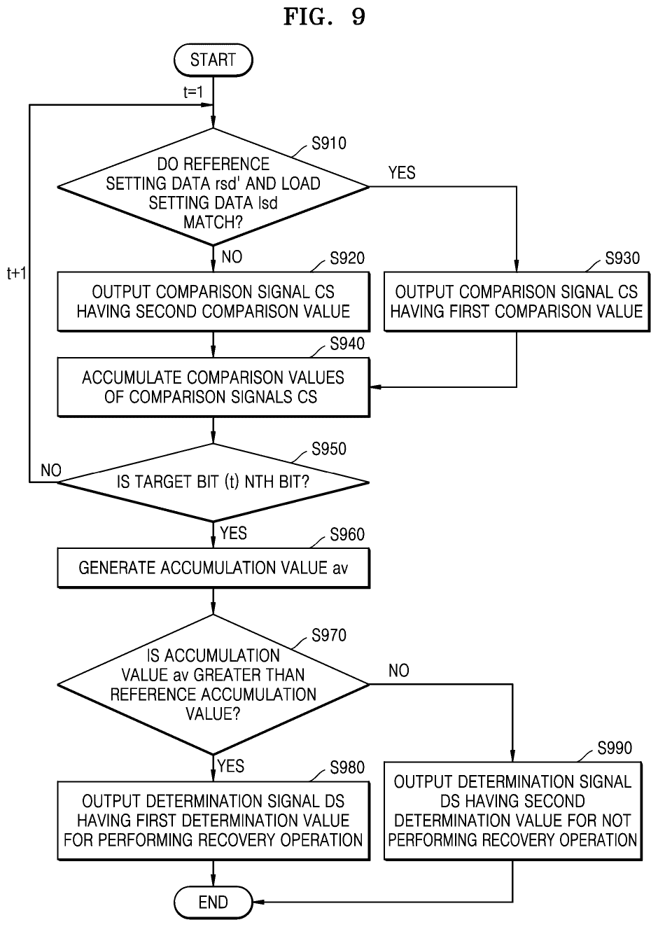

FIG. 9 is a flowchart for describing an operating method of the recovery circuit, according to an embodiment. More particularly, FIG. 9 illustrates the operating method of the recovery circuit 270′ shown in FIG. 6. The recovery circuit 270′ shown in FIG. 6 may include the accumulator 273. The operating method shown in FIG. 9 may be performed in operations S730 and S740 shown in FIG. 7. Operations S710 and S720 shown in FIG. 7 may be performed prior to operation S910 shown in FIG. 9. Same descriptions as those provided above will not be given.

Referring to FIGS. 6 and 9, in operation S910, the recovery circuit 270′ determines whether the reference setting data rsd′ and the load setting data lsd match. When the target bit t is the first bit, the comparison circuit 271 may compare the bit value of the first bit of the load setting data lsd and the bit value of the first bit of the reference setting data rsd′ to determine a result and determine whether the bit value of the first bit of the load setting data lsd′ and the bit value of the first bit of the reference setting data rsd′ match based on the result. The comparison circuit 271 may perform operation S920 when the reference setting data rsd′ and the load setting data lsd do not match, and may perform operation S930 when the reference setting data rsd′ and the load setting data lsd match. The result may be a first comparison value or a second comparison value different from the first comparison value.

In operation S920, when the reference setting data rsd′ and the load setting data lsd do not match, the recovery circuit 270 outputs the comparison signal CS having the second comparison value. In operation S930, when the reference setting data rsd′ and the load setting data lsd match, the recovery circuit 270 outputs the comparison signal CS having the first comparison value. For example, the first comparison value may be 0, and the second comparison value may be 1. However, the inventive concept is not limited thereto.

In operation S940, the recovery circuit 270′ accumulates the comparison values of the comparison signals CS.

In operation S950, the recovery circuit 270′ confirms whether the target bit t is an Nth bit. When the target bit t is the Nth bit, the recovery circuit 270′ performs operation S960. When the target bit t is not the Nth bit, the recovery circuit 270′ repeats the process from operation S910. That is, when the target bit t is not the Nth bit, i.e., the last bit among the N bits of the load setting data lsd, the process may be performed again from operation S910 with respect to a next target bit t. For example, in operation S950, the first bit, i.e., the target bit t, is not the Nth bit, and operation S910 is performed again with respect to a second bit, i.e., a target bit t posterior to the first bit.

In operation S960, the recovery circuit 270′ generates the accumulation value av. For example, the accumulator 273 may accumulate the second comparison value upon receiving the comparison signal CS having the second comparison value, and may accumulate the first comparison value upon receiving the control signal CS having the first comparison value. The accumulator 273 may generate the accumulation value av by accumulating the comparison signals CS for the first bit to the Nth bits of the load setting data lsd.

In operation S970, the recovery circuit 270′ determines whether the accumulation value av is greater than the reference accumulation value. For example, the determination circuit 272 may receive the accumulation value av obtained by accumulating the comparison values for the N bits of the load setting data lsd. When the accumulation value av is greater than the reference accumulation value, the recovery circuit 270′ performs operation S980, and when the accumulation value av is less than or equal to the reference accumulation value, the recovery circuit 270′ performs operation S990.

In operation S980, when the accumulation value av is greater than the reference accumulation value, the recovery circuit 270′ outputs the determination signal DS having the first determination value. For example, when at least a pair of the bit values of all of the bits of the load setting data lsd and the bit values of all of the bits of the reference setting data rsd′ do not match, the accumulation value av may be greater than the reference accumulation value. For example, it is assumed that the accumulation value av is 1 and the reference accumulation value is 0. The determination circuit 272 may output the determination signal DS having the first determination value for performing the recovery operation.

In operation S990, when the accumulation value av is less than or equal to the reference accumulation value, the recovery circuit 270′ may output the determination signal DS having the second determination value. For example, when the bit values of all the bits of the load setting data lsd and the bit values of all the bits of the reference setting data rsd′ match, the accumulation value av may be equal to the reference accumulation value. For example, the accumulation value av may be 0, and the reference accumulation value may also be 0. The determination circuit 272 may output the determination signal DS having the second determination value for not performing the recovery operation.

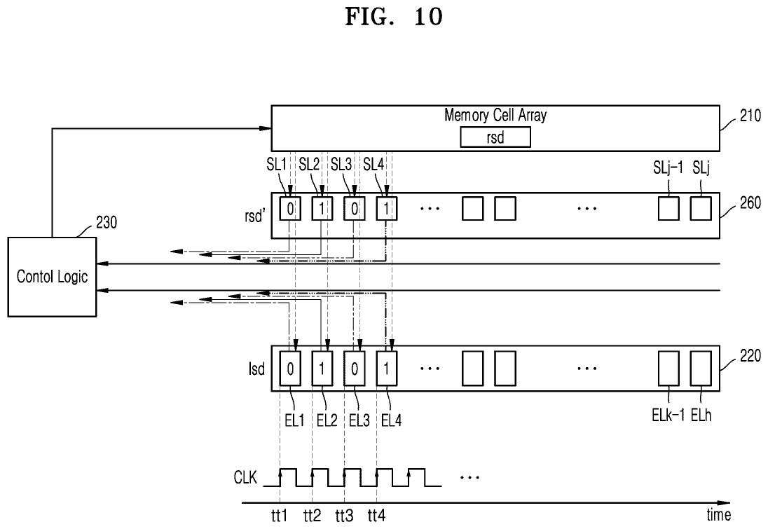

FIG. 10 is a diagram for describing operations of the control logic 230 according to an embodiment. Same descriptions as those provided above will not be given.

Referring to FIG. 10, the memory cell array 210 may be configured to store the reference setting data rsd. For example, the reference setting data rsd may include N pieces of bit data.

The page buffer 260 may include a plurality of latches. For example, the page buffer 260 may include a plurality of sensing latches SL1 to SLj (where j is a positive integer). However, the inventive concept is not limited thereto. The reference setting data rsd stored in the memory cell array 210 may be stored in the page buffer 260. The reference setting data rsd may be loaded to at least one of the sensing latches SL1 to SLj of the page buffer 260 and stored as the reference setting data rsd′. For example, a bit value of the first bit of the reference setting data rsd may be stored in a first sensing latch SL1, a bit value of a second bit may be stored in a second sensing latch SL2, a bit value of a third bit may be stored in a third sensing latch SL3, and a bit value of a fourth bit may be stored in a fourth sensing latch SL4.

The latch circuit 220 may include the plurality of latches. For example, the latch circuit 220 may include a plurality of E-fuse latches EL1 to ELh (where h is a positive integer). However, the inventive concept is not limited thereto. The reference setting data rsd stored in the memory cell array 210 may be loaded to the latch circuit 220 and stored as the load setting data lsd. For example, the load setting data lsd may include N pieces of bit data.

The reference setting data rsd may be loaded to at least one of the plurality of E-fuse latches EL1 to ELh and stored as the load setting data lsd. For example, the bit value of the first bit of the reference setting data rsd may be stored in a first E-fuse latch EL1 as the bit value of the first bit of the load setting data lsd. An address of the first E-fuse latch EL1 may include a first address. For example, the first E-fuse latch EL1 may include a latch having an address of 0x0000. The bit value of the second bit of the reference setting data rsd may be stored in a second E-fuse latch EL2 as the bit value of the second bit of the load setting data lsd. An address of the second e-fuse latch EL2 may include a second address. For example, the second e-fuse latch EL2 may include a latch having an address of 0x0001.

The control logic 230 may determine whether the reference setting data rsd′ stored in the page buffer 260 and the load setting data lsd stored in the latch circuit 220 match. The control logic 230 may determine whether the load setting data lsd and the reference setting data rsd′ match for each pair of bits. In an embodiment, the control logic 230 determines whether the load setting data lsd and the reference setting data rsd′ match for each pair of bits, based on the clock signal CLK. For example, the clock signal CLK may include an internal clock signal of the memory device.

For example, in response to a rising edge at a first time point tt1 of the clock signal CLK, the control logic 230 may determine whether the bit value of the first bit of the reference setting data rsd′ stored in the first sensing latch SL1 and the bit value of the first bit of the load setting data lsd stored in the first E-fuse latch EL1 match. The bit value stored in the first sensing latch SL1 and the bit value stored in the first E-fuse latch EL1 may match as 0. Although FIG. 10 illustrates that the control logic 230 performs the error determination operation in response to the rising edge shifted from a low level to a high level, the embodiments are not limited thereto, and the error determination operation may also be performed in response to a falling edge shifted from a high level to a low level.

In response to a rising edge of the clock signal CLK at a second time point tt2, the control logic 230 may determine whether the bit value of the second bit of the reference setting data rsd′ stored in the second sensing latch SL2 and the bit value of the second bit of the load setting data lsd stored in the second E-fuse latch EL2 match. The bit value stored in the second sensing latch SL2 and the bit value stored in the second E-fuse latch EL2 may match as 1.

When bit values of bits of the load setting data lsd match bit values of bits of corresponding reference setting data rsd′, the control logic 230 does not perform the recovery operation.

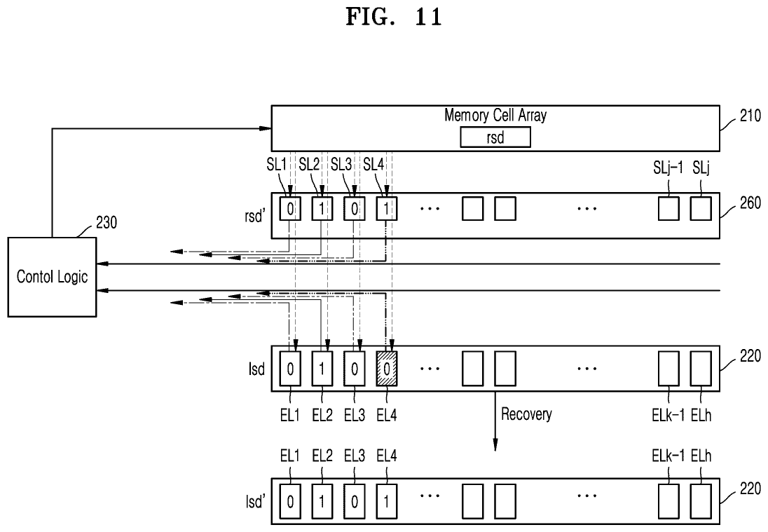

FIG. 11 is a diagram for describing the recovery operation according to an embodiment. Same descriptions as those with reference to FIG. 10 will not be given.

Referring to FIG. 11, the control logic 230 determines whether the reference setting data rsd′ stored in the page buffer 260 and the load setting data lsd stored in the latch circuit 220 match.

For example, the control logic 230 may determine that the bit value of the first bit of the reference setting data rsd′ stored in the first sensing latch SL1 and the bit value of the first bit of the load setting data lsd stored in the first E-fuse latch EL1 match.

The control logic 230 may determine that the bit value of the second bit of the reference setting data rsd′ stored in the second sensing latch SL2 and the bit value of the second bit of the load setting data lsd stored in the second E-fuse latch EL2 match.

The control logic 230 may determine that the bit value of the third bit of the reference setting data rsd′ stored in the third sensing latch SL3 and the bit value of the third bit of the load setting data lsd stored in a third E-fuse latch EL3 match.

The control logic 230 may determine that the bit value of the fourth bit of the reference setting data rsd′ stored in the fourth sensing latch SL4 and the bit value of the fourth bit of the load setting data lsd stored in the fourth e-fuse latch EL4 do not match.

From among the bits of the load setting data lsd, the control logic 230 may determine a bit, in which the bit value of the load setting data lsd and the bit value of the reference setting data rsd′ do not match, as an error bit. The control logic 230 may determine the fourth bit of the load setting data lsd as the error bit.

When the load setting data lsd and the reference setting data rsd′ do not match, the control logic 230 may determine that a temporary error has occurred in the latch circuit 220. When the control logic 230 determines that the reference setting data rsd′ and the load setting data lsd do not match, the control logic 230 may perform the recovery operation. The control logic 230 may load the reference setting data rsd, which is stored in the memory cell array 210, back to the latch circuit 220. The reference setting data rsd loaded back may be stored in the latch circuit 220 as load setting data lsd′. For example, the bit value of the fourth bit of the load setting data lsd stored in the fourth E-fuse latch EL4 of the latch circuit 220 may become identical to its bit value in the reference setting data rsd. For example, the bit value of the fourth bit of the load setting data lsd stored in the fourth E-fuse latch EL4 may be overwritten with the bit value of the fourth bit of the reference setting data rsd, which is stored in the memory cell array 210 in the recovery operation.

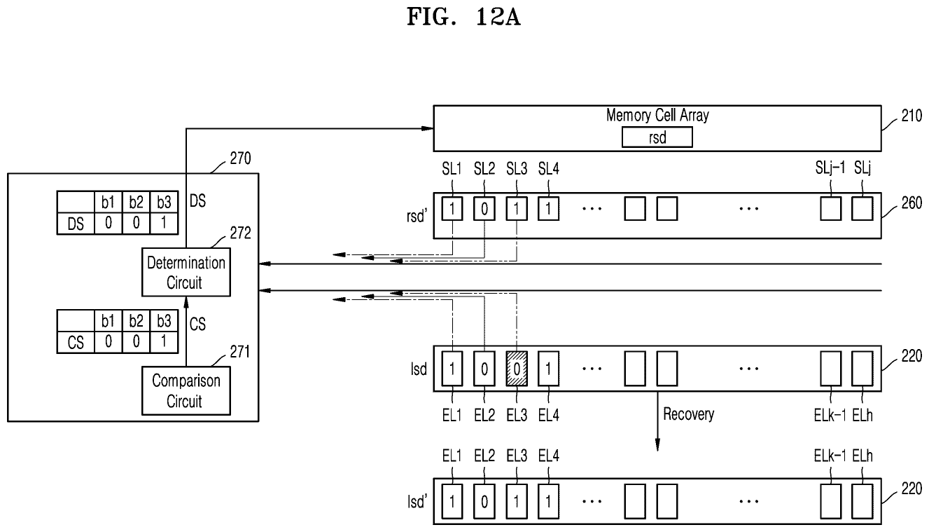

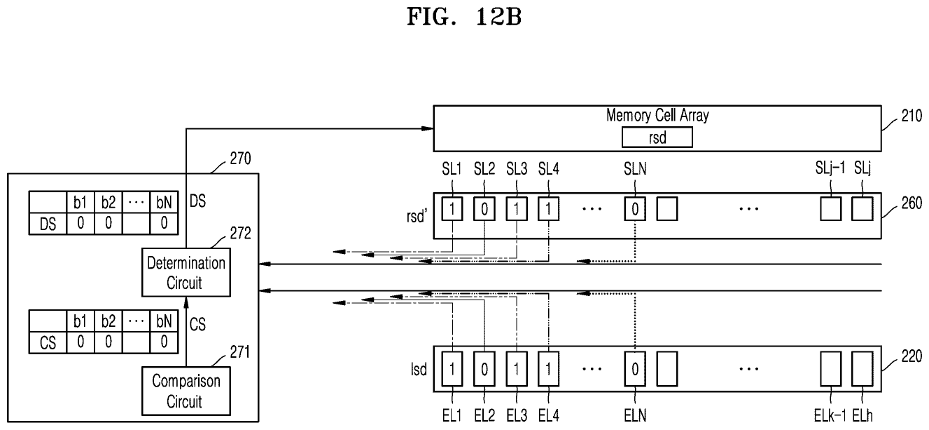

FIG. 12A is a block diagram for describing operations of the recovery circuit 270 according to an embodiment. FIG. 12A illustrates a case in which an error bit has been found in the load setting data lsd. Same descriptions as those provided above will not be given.

Referring to FIG. 12A, the comparison circuit 271 may compare the load setting data lsd and the reference setting data rsd′ for each pair of bits. The comparison circuit 271 may be configured to determine whether the load setting data lsd and the reference setting data rsd′ match for each pair of bits and output the comparison signal for each pair of bits.

When the reference setting data rsd′ and the load setting data lsd match, the comparison circuit 271 outputs the comparison signal CS having the first comparison value. When the reference setting data rsd′ and the load setting data lsd do not match, the comparison circuit 271 outputs the comparison signal having the second comparison value. The first comparison value and the second comparison value are different from each other. For example, the first comparison value may be 0, and the second comparison value may be 1. However, the embodiments are not limited thereto. For example, the first comparison value may be 1, and the second comparison value may be 0.

The determination circuit 272 may control the recovery operation based on the comparison signal CS. The determination circuit 272 may generate the determination signal DS to control the recovery operation, based on the comparison signal CS. In an embodiment, upon receiving the comparison signal CS having the second comparison value, the determination circuit 272 generates the determination signal DS for performing the recovery operation. Upon receiving the comparison signal CS having the second comparison value, the determination circuit 272 generates the determination signal DS including the first determination value for performing the recovery operation.

Upon receiving the comparison signal CS having the first comparison value, the determination circuit 272 generates the determination signal DS for not performing the recovery operation. Upon receiving the comparison signal CS having the first comparison value, the determination circuit 272 may immediately generate the determination signal DS including the second determination value. The first determination value and the second determination value are different from each other. For example, the first determination value may be 1, and the second determination value may be 0. However, the embodiments are not limited thereto. For example, the first determination value may be 0, and the second determination value may be 1.

For example, the comparison circuit 271 may determine that a bit value of a first bit b1 of the reference setting data rsd′ stored in the first sensing latch SL1 and a bit value of a first bit b1 of the load setting data lsd stored in the first e-fuse latch EL1 match. The comparison circuit 271 may output the comparison signal CS having the first comparison value. For example, the comparison signal CS for the first bit b1 of the load setting data lsd may be 0. Since the determination circuit 272 has received the comparison signal CS having the first comparison value, the determination circuit 272 may generate the determination signal DS including the second determination value for the first bit b1. For example, the determination signal DS for the first bit b1 of the load setting data lsd may be 0.

The comparison circuit 271 may determine that the bit value of the second bit b2 of the reference setting data rsd′ stored in the second sensing latch SL2 and the bit value of the second bit b2 of the load setting data lsd stored in the second E-fuse latch EL2 match. The comparison circuit 271 may output the comparison signal CS having the first comparison value. For example, the comparison signal CS for the second bit b2 of the load setting data lsd may be 0. Since the determination circuit 272 has received the comparison signal having the first comparison value for the second bit b2, the determination circuit 272 may generate the determination signal DS including the second determination value for the second bit b2. For example, the determination signal DS for the second bit b2 of the load setting data lsd may be 0.

The comparison circuit 271 may determine that the bit value of the third bit of the reference setting data rsd′ stored in the third sensing latch SL3 and the bit value of the third bit of the load setting data lsd stored in the third E-fuse latch EL3 do not match.

Accordingly, the comparison circuit 271 may determine the third bit of the load setting data lsd as the error bit. The comparison circuit 271 may output the comparison signal CS having the second comparison value when an error bit is discovered. For example, the comparison signal CS for the third bit of the load setting data lsd may be 1. Since the determination circuit 272 receives the comparison signal CS having the second comparison value, the determination circuit 272 may generate the determination signal DS including the first determination value for the third bit b3. For example, the determination signal DS of the third bit b3 of the load setting data lsd may be 1. The recovery operation may be performed with respect to the load setting data lsd, based on the determination signal DS having the first determination value. While the embodiment described with reference to FIG. 12A corresponds to an example for describing the operations of the recovery circuit 270, the inventive concept is not limited thereto.

FIG. 12B is a block diagram for describing operations of the recovery circuit 270 according to an embodiment. Compared with FIG. 12A, FIG. 12B illustrates a case in which an error bit has not been found in the load setting data lsd. Same descriptions as those provided above will not be given.

Referring to FIG. 12B, the comparison circuit 271 may output the comparison signal CS having the value of 0 for the first bit b1 of the load setting data lsd. Since the determination circuit 272 has received the comparison signal CS having the first comparison value, the determination circuit 272 may generate the determination signal DS having the second determination value of 0 for the first bit b1.

The comparison circuit 271 may output the comparison signal CS having value of 0, i.e., the first comparison value, for the second bit b2 of the load setting data lsd. Since the determination circuit 272 receives the comparison signal CS having the first comparison value, the determination circuit 272 may generate the determination signal DS including value of 0, i.e., the second determination value, for the second bit b2.

The comparison circuit 271 and the determination circuit 272 may also generate the comparison signal CS and the determination signal DS for other bits of the load setting data lsd. Under the assumption that there is no error bit in the load setting data lsd, the comparison circuit 271 may determine whether the reference setting data rsd′ and the load setting data lsd match to the Nth bit bN. For example, the comparison circuit 271 may output the comparison signal CS having the value of 0 for the Nth bit bN of the load setting data lsd. Having received the comparison signal CS having the first comparison value, the determination circuit 272 may generate the determination signal DS having the second determination value of 0 for the Nth bit bN. Since a temporary error has not occurred in the latch circuit 220, the recovery operation may be not needed to be performed for the latch circuit 220. Based on the determination signal DS having the second determination value, the recovery operation need not be performed with respect to the load setting data lsd. While the embodiment described with reference to FIG. 12B corresponds to an example for describing the operations of the recovery circuit 270, the inventive concept is not limited thereto.

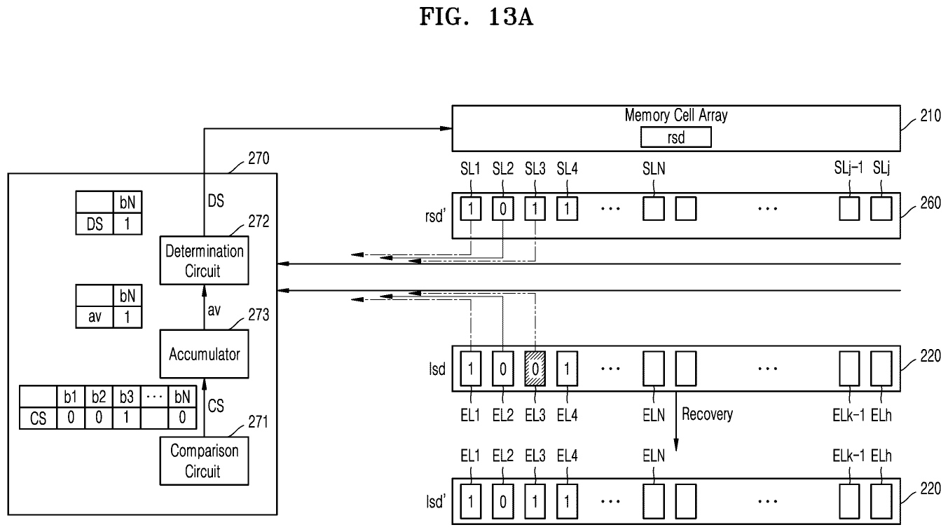

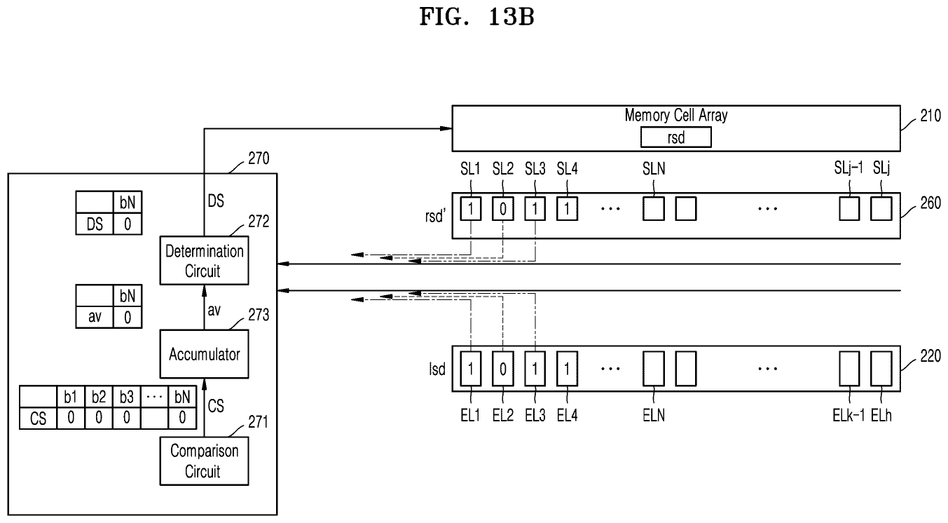

FIG. 13A is a block diagram for describing operations of the accumulator 273 according to an embodiment. FIG. 13A illustrates a case in which an error bit has been found in the load setting data lsd. Same descriptions as those provided above will not be given.

Referring to FIG. 13A, the recovery circuit 270 may include the accumulator 273. The comparison circuit 271 may be configured to determine whether the load setting data lsd and the reference setting data rsd′ match for each pair of bits and output the comparison signal for each pair of bits. The accumulator 273 may be configured to generate an accumulation value av by accumulating comparison values of the comparison signal CS. The accumulator 273 may accumulate comparison values of the comparison signal CS for the N bits. In FIG. 13A, it is assumed that the third bit b3 of the load setting data lsd is an error bit.

For example, the comparison circuit 271 may output the comparison signal CS having the first comparison value, because the bit value of the first bit b1 of the reference setting data rsd′ stored in the first sensing latch SL1 and the bit value of the first bit b1 of the load setting data lsd stored in the first E-fuse latch EL1 match. For example, the first comparison value may be 0. The accumulator 273 may accumulate the first comparison value of the first bit b1.

The comparison circuit 271 may output the comparison signal CS having the first comparison value, because the bit value of the second bit b2 of the reference setting data rsd′ stored in the second sensing latch SL2 and the bit value of the second bit b2 of the load setting data lsd stored in the second E-fuse latch EL2 match. For example, the first comparison value may be 0. The accumulator 273 may accumulate the first comparison value of the second bit b2 on the comparison value of the first bit b1.

The comparison circuit 271 may output the comparison signal CS having the second comparison value, because the bit value of the third bit b3 of the reference setting data rsd′ stored in the third sensing latch SL3 and the bit value of the third bit b3 of the load setting data lsd stored in the third E-fuse latch EL3 do not match. For example, the second comparison value may be 1. The accumulator 273 may accumulate the second comparison value of the third bit b3 on the comparison values of the first bit b1 and the second bit b2.

The comparison circuit 271 may output the comparison signal CS for the first bit b1 to the Nth bit bN of the load setting data lsd. The accumulator 273 may finally generate the accumulation value av for the Nth bit bN. The accumulation value av may include a value obtained by accumulating comparison values for the first bit b1 to the Nth bit bN of the load setting data lsd. When it is assumed that only the third bit b3 of the load setting data lsd is an error bit, the accumulation value av may be 1. For example, if two bits were error bits, the accumulation value av may be 2; if three bits were error bits, the accumulation value av may be 3, etc.

The determination circuit 272 may control the recovery operation based on the accumulation value av. The determination circuit 272 may generate the determination signal DS for controlling the recovery operation, based on the accumulation value av. When the accumulation value av is greater than the reference accumulation value, the determination circuit 272 may generate the determination signal DS for performing the recovery operation. For example, the reference accumulation value may be 0, and the accumulation value av is greater than the reference accumulation value, accordingly, the determination circuit 272 may generate the determination signal including the first determination value for performing the recovery operation. For example, the first determination value may be 1. However, the inventive concept is not limited thereto. While the embodiment described with reference to FIG. 13A corresponds to an example for describing the operations of the recovery circuit 270, the inventive concept is not limited thereto.

FIG. 13B is a block diagram for describing operations of the accumulator 273 according to an embodiment. Compared with FIG. 13A, FIG. 13B illustrates a case in which an error bit has not been found in the load setting data lsd. Same descriptions as those provided above will not be given.

In FIG. 13B, a case in which there is no error bit in the load setting data lsd is assumed. The comparison circuit 271 may output the comparison signal CS for the first bit b1 to the Nth bit bN of the load setting data lsd. The accumulator 273 may finally generate the accumulation value av for the Nth bit bN.

Since there is no error bit in the load setting data lsd, the accumulation value av may be 0. The accumulator 273 may deliver the accumulation value av to the determination circuit 272. The determination circuit 272 may generate the determination signal DS for controlling the recovery operation, based on the accumulation value av. When the accumulation value av is the reference accumulation value or less, the determination circuit 272 may generate the determination signal DS for not performing the recovery operation. For example, the reference accumulation value may be 0, and the accumulation value av for the Nth bit bN may be 0. Since the accumulation value av is the reference accumulation value, the determination circuit 272 may generate the determination signal DS including the second determination value for not performing the recovery operation. For example, the second determination value may be 0. However, the inventive concept is not limited thereto. While the embodiment described with reference to FIG. 13B corresponds to an example for describing the operations of the recovery circuit 270, the inventive concept is not limited thereto.

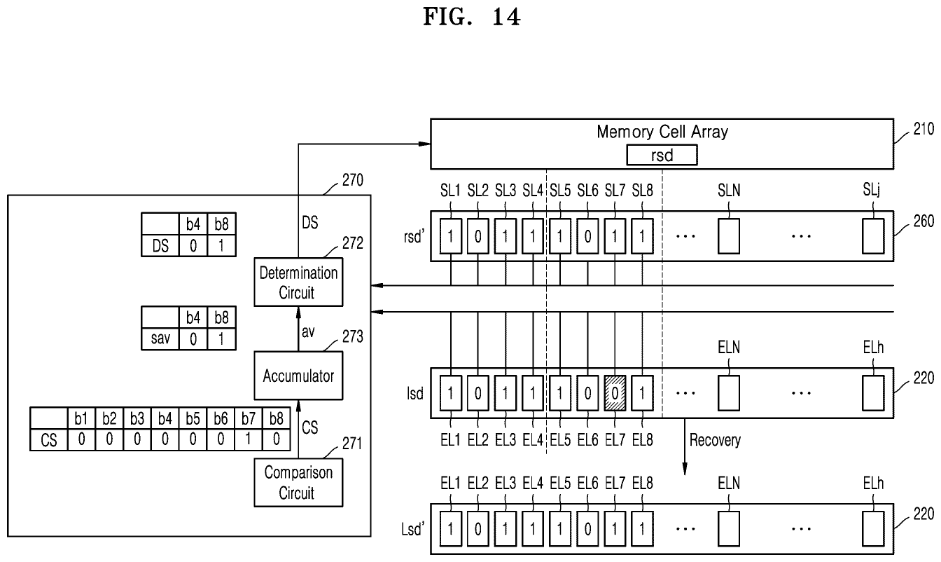

FIG. 14 is a diagram for describing sub-accumulation data according to an embodiment. In FIG. 14, it is assumed that a seventh bit b7 of the load setting data is an error bit. Same descriptions as those provided above will not be given.

Referring to FIG. 14, the comparison circuit 271 may be configured to compare the bit value of each bit of the load setting data lsd with the bit value of each bit of the reference setting data rsd′ and output the comparison signal CS. The comparison circuit 271 may output the comparison signal CS having the second comparison value, because a bit value of a seventh bit b7 of the reference setting data rsd′ stored in the seventh sensing latch SL7 and a bit value of the seventh bit b7 of the load setting data lsd stored in the seventh e-fuse latch EL7 do not match. For example, the second comparison value may be 1.

In an embodiment, the accumulator 273 generates a sub-accumulation value sav by accumulating k times (where k is a positive integer of N binominal) the comparison value of the comparison signal CS. For example, when the load setting data lsd includes N bit (where N is a positive integer), the accumulator 273 may generate the sub-accumulation value sav by accumulating comparison values of the comparison signals CS for respective k bits. The sub-accumulation value sav may include a value obtained by accumulating comparison values of the load setting data lsd in k-bit unit. Although FIG. 14 illustrates a case in which k is 4, this is merely an example, and the embodiment is not necessarily limited thereto.

For example, the accumulator 273 may generate the sub-accumulation value sav by accumulating comparison values for four bits of the load setting data lsd. The accumulator 273 may accumulate the comparison values for each four bits of the load setting data lsd. For example, the accumulator 273 may generate the sub-accumulation value sav by accumulating respective comparison values of the first bit b1 to the fourth bit b4. The sub-accumulation value sav for the fourth bit b4 may include an accumulation value obtained by accumulating the respective comparison values of the first bit b1 to the fourth bit b4. Since there is no error bit from the first bit b1 to the fourth bit b4 of the load setting data lsd, the sub-accumulation value sav for the fourth bit b4 may be 0.

The determination circuit 272 may control the recovery operation based on the sub-accumulation value sav. The determination circuit 272 may generate the determination signal DS for controlling the recovery operation, based on the sub-accumulation value av. The determination circuit 272 generates the determination signal DS based on the sub-accumulation value av, and thus may generate the determination signal DS in k-bit unit.

When the sub-accumulation value sav is equal to the reference accumulation value or less, the determination circuit 272 may generate the determination signal for not performing the recovery operation. For example, when the sub-accumulation value sav is equal to the reference accumulation value or less, the determination circuit 272 may generate the determination signal DS including the second determination value for not performing the recovery operation. For example, under the assumption that the reference accumulation value is 0, the determination circuit 272 may generate the determination signal DS including the second determination value, since the sub-accumulation value sav for the fourth bit b4 is 0 and corresponds (e.g., is equal) to the reference accumulation value. The determination circuit 272 may generate the determination signal DS having the value of 0 for the fourth bit b4.

The accumulator 273 may generate a sub-accumulation value sav by accumulating respective comparison values of the fifth bit b5 to the eighth bit b8. The sub-accumulation value sav for the eighth bit b8 may include an accumulation value obtained by accumulating the respective comparison values of the fifth bit b5 to the eighth bit b8. As the seventh bit b7 of the load setting data lsd corresponds to the error bit, the sub-accumulation value sav for the eighth bit b8 may be 1.

When the sub-accumulation value sav is greater than the reference accumulation value, the determination circuit 272 may generate the determination signal DS for performing the recovery operation. For example, when the sub-accumulation value sav is greater than the reference accumulation value, the determination circuit 272 may generate the determination signal DS including the first determination value for performing the recovery operation. For example, under the assumption that the reference accumulation value is 0, the sub-accumulation value sav for the eighth bit b8 is 1 and thus is greater than the reference accumulation value, and therefore, the determination circuit 272 may generate the determination signal DS including the first determination value. The determination circuit 272 may generate the determination signal DS having the value of 1 for the eighth bit b8. The recovery circuit 270 may perform the recovery operation based on the sub-accumulation value for the eighth bit b8.

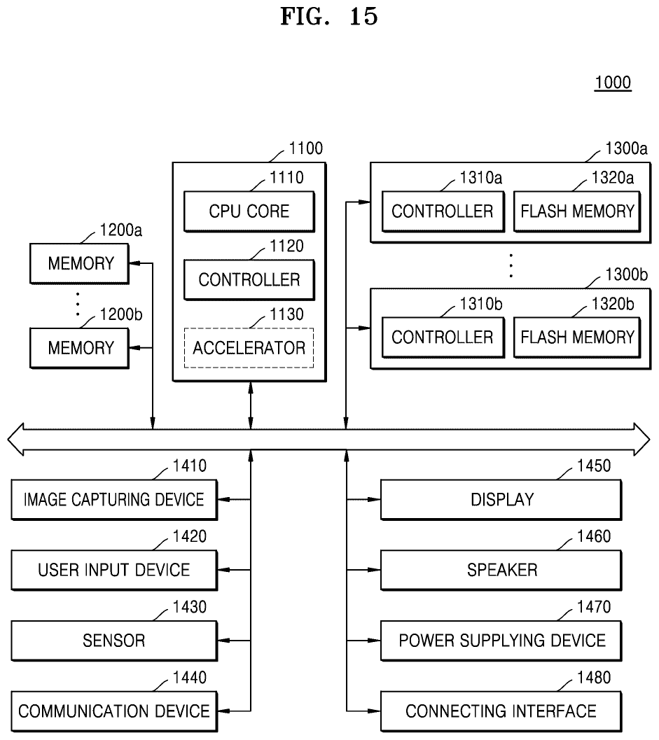

FIG. 15 illustrates a system 1000 to which a memory device is applied, according to an embodiment. Non-volatile memory (NVM) devices 1320a and 1320b may include the memory device (e.g., the memory device 200 shown in FIG. 1) described in the inventive concept. Storage devices 1300a and 1300b shown in FIG. 15 may include a memory system (e.g., the memory system 10 shown in FIG. 1) described in the inventive concept. The system 1000 shown in FIG. 15 may be a mobile system such as mobile phones, smart phones, tablet personal computers (PC), wearable apparatuses, healthcare apparatuses, or Internet of Things (IoT) apparatuses. However, the system 1000 shown in FIG. 15 is not limited to the mobile system, and may also include personal computers, laptop computers, servers, media players, or automotive devices such as navigation devices.

Referring to FIG. 15, the system 1000 may include a main processor 1100, a memory 1200a, a memory 1200b, a storage device 1300a, and a storage device 1300b, and may additionally include one or more of an image capturing device 1410, a user input device 1420, a sensor 1430, a communication device 1440, a display 1450, a speaker 1460, a power supplying device 1470, and a connecting interface 1480.

The main processor 1100 may control general operations of the system 1000, and more particularly, operations of other components included in the system 1000. The main processor 1100 may be implemented such as a general-purpose processor, a dedicated processor, an application processor, or the like.

The main processor 1100 may include one or more CPU cores 1110, and may further include a controller 1120 for controlling the memory 1200a and the memory 1200b and/or the storage device 1300a and the storage device 1300b. According to embodiments, the main processor 1100 may further include an accelerator 1130, which is a dedicated circuit for high-rate data calculation for artificial intelligence (AI) data calculation and the like. The accelerator 1130 may include a Graphics Processing unit (GPU), a Neural Processing Unit (NPU), and/or a Data Processing Unit (DPU), and may be implemented as separate chips physically independent from other components of the main processor 1100.

The memories 1200a and 1200b may be used as a memory device of the system 1000 and may include a volatile memory such as SRAM and/or DRAM, and may also include a nonvolatile memory such as a flash memory, PRAM, and/or RRAM. The memories 1200a and 1200b may also be implemented in a same package as the main processor 1100.

The storage devices 1300a and 1300b may function as non-volatile storage device configured to store data regardless of a power supply, and may have a storage capacity relatively greater than the memory 1200a and 1200b. The storage devices 1300a and 1300b may include memory controllers 1310a and 1310b and non-volatile memory devices 1320a and 1320b configured to store data under control of the memory controllers 1310a and 1310b. The non-volatile memory devices 1320a and 1320b may include a flash memory having a two-dimensional (2D) structure or a three-dimensional (3D) Vertical NAND (V-NAND) structure, but may also include different kinds of non-volatile memories, e.g., PRAM and/or RRAM. The memory device (e.g., the memory device 200 shown in FIG. 1) described with reference to FIGS. 1 to 14 may be applied to the non-volatile memory device 1320a and 1320b shown in FIG. 15.

The storage devices 1300a and 1300b may be included in the system 1000 in the form of being physically separated from the main processor 1100, or may be implemented a same package with the main processor 1100. In addition, the storage devices 1300a and 1300b may have the form of a solid state device (SSD) or a memory card, and therefore may be detachably combined with other components of the system 1000 through an interface such as a connection interface 1480 to be described below. The storage devices 1300a and 1300b may include devices to which standard protocols such as Universal Flash Storage (USF), embedded Multi-Media card (eMMC) or non-volatile memory express (NVMe) are applied, but are not limited thereto.

The image capturing device 1410 may be configured to capture still images or videos, and may include a camera, a camcorder, and/or a webcam. The user input device 1420 may be configured to receive various types of data input from the user of the system 1000, and may include a touch pad, a keypad, a keyboard, a mouse, and/or a microphone. The sensor 1430 may be configured to sense various types of physical quantities that may be obtained from outside of the system and convert the physical quantities that have been sensed into electrical signals. The sensor 1430 may include a temperature sensor, a pressure sensor, a luminance sensor, a position sensor, an acceleration sensor, a biosensor, and/or a gyroscope sensor.

The communication device 1440 may be configured to transmit and receive signals with other devices outside the system 1000 according to various communication protocols. The communication device 1440 may be implemented by including an antenna, a transceiver, and/or a modem. The display 1450 and the speaker 1460 may function as output devices configured to respectively provide visual information and auditory information to the user of the system 1000. The power supplying device 1470 may be configured to appropriately convert power supplied from a battery (not shown) embedded in the system 1000 and/or external power source and provide the power to the components of the system 1000.

The connecting interface 1480 may be configured to provide connection between the system 1000 and an external device connected to the system 1000 and capable of exchange data with the system 1000. The connecting interface 1480 may be implemented in various types of interfaces, e.g., Advanced Technology Attachment (ATA), Serial ATA (SATA), SCSI(Small Computer Small Interface), SAS(Serial Attached SCSI), PCI(Peripheral Component Interconnection), PCIe(PCI express), NVMe, IEEE 1394, a universal serial bus (USB), a secure digital (SD) card, a multi-media card (MMC), an eMMC, a universal flash storage (UFS), an embedded UFS (eUFS), a compact flash (CF) card interface, and the like.

While the inventive concept has been particularly shown and described with reference to embodiments thereof, it will be understood that various changes in form and details may be made therein without departing from the spirit and scope of the following claims.

What is claimed is:

1. A memory device comprising:
a memory cell array comprising a plurality of memory cells and storing reference setting data comprising information regarding setting operations of the memory device;
a control logic configured to control memory operations on the memory cell array; and
a latch circuit comprising a plurality of latches,
wherein the reference setting data is loaded from the memory cell array and stored as load setting data in the latch circuit,
wherein the control logic is further configured to:
compare the reference setting data stored in the memory cell array, with the load setting data stored in the latch circuit to determine whether the reference setting data and the load setting data match, and
perform a recovery operation to load the reference setting data from the memory cell array back to the latch circuit when the control logic determines that the reference setting data and the load setting data do not match.

2. The memory device of claim 1, wherein
the control logic is further configured to
compare the reference setting data with the load setting data for each pair of bits, determine a bit of the load setting data, in which a bit value of the load setting data and a bit value of the reference setting data do not match, as an error bit, and
perform the recovery operation when at least one of the bits of the load setting data is an error bit.

3. The memory device of claim 2, wherein
the control logic is further configured to
compare the reference setting data with the load setting data for each bit until the error bit is determined from among the bits of the load setting data, and
perform the recovery operation when the error bit of the load setting data is determined.

4. The memory device of claim 2, wherein
the control logic is further configured to
compare every bit value of the load setting data with every bit value of the reference setting data,
perform the recovery operation when at least one of the bits of the load setting data is the error bit, and
not perform the recovery operation when none of the bits of the load setting data is the error bit.

5. The memory device of claim 1, further comprising a page buffer connected to the memory cell array,
wherein the reference setting data stored in the memory cell array is stored in the page buffer,
wherein the control logic is further configured to compare the reference setting data stored in the page buffer with the load setting data stored in the latch circuit to determine whether the reference setting data and the load setting data match.

6. The memory device of claim 5, wherein the control logic is further configured to perform the recovery operation when determining that the reference setting data stored in the page buffer and the load setting data stored in the latch circuit do not match.

7. The memory device of claim 1, wherein
the control logic is further configured to,
after a preset period of time after the performing of the recovery operation, compare the reference setting data stored in the memory cell array with the load setting data stored in the latch circuit to determine whether the reference setting data and the load setting data match, and
stop the recovery operation when determining that the reference setting data and the load setting data do not match.

8. The memory device of claim 1, wherein the control logic is further configured to perform the recovery operation when the memory device is in an idle state.

9. A memory device comprising:
a memory cell array storing reference setting data comprising information regarding setting operations of the memory device;
a latch circuit in which the reference setting data is loaded from the memory cell array and stored as load setting data;
a comparison circuit configured to compare the reference setting data output from the memory cell array and the load setting data output from the latch circuit to output a comparison signal; and
a determination circuit configured to generate a determination signal for controlling a recovery operation to load the reference setting data from the memory cell array back to the latch circuit, based on the comparison signal indicating that the reference setting data and the load setting data do not match.

10. The memory device of claim 9, wherein the comparison circuit is further configured to compare the reference setting data with the load setting data for each bit to determine whether the reference setting data and the load setting data match, and output the comparison signal for each bit.

11. The memory device of claim 10, wherein the comparison circuit is further configured to:
output the comparison signal having a first comparison value when the reference setting data and the load setting data match, and
output the comparison signal having a second comparison value different from the first comparison value when the reference setting data and the load setting data do not match.

12. The memory device of claim 11,
wherein the determination circuit is further configured to,
upon receiving the comparison signal having the second comparison value, generate the determination signal including a first determination value for performing the recovery operation.

13. The memory device of claim 11, further comprising
an accumulator configured to generate an accumulation value by accumulating comparison values of the comparison signal, and
wherein the determination circuit is further configured to generate the determination signal based on the accumulation value.

14. The memory device of claim 13, wherein
the determination circuit is further configured to
generate the determination signal comprising a first determination value for performing the recovery operation when the accumulation value is greater than a reference accumulation value, and
generate the determination signal comprising a second determination value for not performing the recovery operation when the accumulation value is less than or equal to the reference accumulation value.

15. The memory device of claim 13,
wherein the load setting data comprises N-bit data, where N is a positive integer,
wherein the accumulator is further configured to generate a sub-accumulation value by accumulating k times the comparison value of the comparison signal, where k is a positive integer less than or equal to N, and
wherein the determination circuit is further configured to generate the determination signal based on the sub-accumulation value.

16. The memory device of claim 9, wherein the comparison circuit comprises an XOR gate receiving the reference setting data as a first input and the load setting data as a second input and configured to compare the first input with the second input to output the comparison signal.

17. An operating method of a memory device, the operating method comprising:
outputting, from a memory cell array of the memory device to a page buffer of the memory device, setting data comprising information regarding setting operations of the memory device;
outputting the setting data from the memory cell array to a latch circuit of the memory device;
comparing the setting data stored in the page buffer with the setting data stored in the latch circuit for outputting a comparison signal; and
generating a determination signal for controlling a recovery operation to output the setting data from the memory cell array back to the latch circuit, based on the comparison signal.

18. The operating method of claim 17, wherein the outputting of the comparison signal comprises:
outputting the comparison signal having a first value when the setting data stored in the page buffer and the setting data stored in the latch circuit match; and
outputting the comparison signal having a second value when the setting data stored in the page buffer and the setting data stored in the latch circuit do not match, and
wherein the first comparison value is different from the second comparison value.

19. The operating method of claim 18, wherein the generating of the determination signal comprises:
generating the determination signal for not performing the recovery operation when the comparison signal having the first comparison value is output; and
generating the determination signal for performing the recovery operation when the comparison signal having the second comparison value is output.

20. The operating method of claim 18, further comprising
generating an accumulation value by accumulating a comparison value of the comparison signal, and
the generating of the determination signal comprises:
generating the determination signal comprising a first determination value for performing the recovery operation when the accumulation value is greater than a reference accumulation value; and
generating the determination signal comprising a second determination value for not performing the recovery operation when the accumulation value is less than or equal to the reference accumulation value.
